(19) United States
(12) Patent Application Publication
(10) Pub. No.: US 2025/0226032 A1
(43) Pub. Date: Jul. 10, 2025

(54) MEMORY DEVICE AND OPERATION METHOD THEREOF

(71) Applicant: SAMSUNG ELECTRONICS CO., LTD., Suwon-si (KR)

(72) Inventors: Sang-Won Park, Suwon-si (KR); Il Han Park, Suwon-si (KR); Garam Kim, Suwon-si (KR); Sangwon Kim, Suwon-si (KR)

(21) Appl. No.: 18/946,289

(22) Filed: Nov. 13, 2024

(30) Foreign Application Priority Data
Jan. 9, 2024 (KR) 10-2024-0003590
Mar. 6, 2024 (KR) 10-2024-0032057
Apr. 30, 2024 (KR) 10-2024-0057749
Oct. 17, 2024 (KR) 10-2024-0142471

(51) Int. Cl. G11C 16/04; G11C 16/28; G11C 16/34

(52) U.S. Cl. CPC G11C 16/0483; G11C 16/28; G11C 16/3459

(57) ABSTRACT

A memory device includes a first cell string that is provided between a first bit line and a common source line and a second cell string that is provided between the first bit line and the common source line. At least two first ground selection transistors among first ground selection transistors of the first cell string have a first program state and remaining first ground selection transistors have an erase state. At least two second ground selection transistors among the second ground selection transistors of the second cell string have the first program state and remaining second ground selection transistors have the erase state.

### CROSS-REFERENCE TO RELATED APPLICATIONS

This application claims priority under 35 U.S.C. § 119 to Korean Patent Application Nos. 10-2024-0003590 filed on Jan. 9, 2024, 10-2024-0032057 filed on Mar. 6, 2024, 10-2024-0057749 filed on Apr. 30, 2024, 10-2024-0142471 filed on Oct. 17, 2024, in the Korean Intellectual Property Office, the disclosures of which are incorporated by reference herein in their entireties.

### BACKGROUND

A semiconductor memory is classified as a volatile memory, which loses data stored therein when a power is turned off, such as a static random access memory (SRAM) or a dynamic random access memory (DRAM) or a nonvolatile memory, which retains data stored therein even when a power is turned off, such as a flash memory, a phase-change RAM (PRAM), a magnetic RAM (MRAM), a resistive RAM (RRAM), or a ferroelectric RAM (FRAM).

The flash memory device is widely used as a high-capacity storage medium. In general, the flash memory device stores data or reads the stored data by controlling levels of various lines (e.g., a string selection line, a word line, and a ground selection line) connected to a plurality of memory cells. When various lines are controlled individually in units of cell strings, the reliability and performance of the flash memory device may be improved, but it is difficult to form lines individually due to the increase in complexity of the process of manufacturing the flash memory device.

### SUMMARY

Implementations of the present disclosure provide a memory device with improved performance and improved reliability and an operation method thereof.

According to an implementation, a memory device includes a first cell string that is provided between a first bit line and a common source line and includes a first string selection transistor connected to a first string selection line and first ground selection transistors respectively connected to a plurality of ground selection lines, and a second cell string that is provided between the first bit line and the common source line and includes a second string selection transistor connected to a second string selection line and second ground selection transistors respectively connected to the plurality of ground selection lines. At least two first ground selection transistors among the first ground selection transistors are configured to have a first program state and remaining first ground selection transistors among the first ground selection transistors are configured to have an erase state. At least two second ground selection transistors among the second ground selection transistors are configured to have the first program state and remaining second ground selection transistors among the second ground selection transistors are configured to have the erase state.

According to an implementation, a memory device includes a first cell string that is connected to a first bit line, a first string selection line, and a plurality of ground selection lines, a second cell string that is connected to the first bit line, a second string selection line, and the plurality of ground selection lines, a third cell string that is connected to the first bit line, a third string selection line, and the plurality of ground selection lines, and a fourth cell string that is connected to the first bit line, a fourth string selection line, and the plurality of ground selection lines. When the first cell string is selected, a first on-voltage is applied to a first ground selection line and a second ground selection line among the plurality of ground selection lines, and a second on-voltage lower than the first on-voltage is applied to remaining ground selection lines among the plurality of ground selection lines other than the first and second ground selection lines. When the second cell string is selected, the first on-voltage is applied to the second ground selection line and a third ground selection line among the plurality of ground selection lines, and the second on-voltage is applied to remaining ground selection lines among the plurality of ground selection lines other than the second and third ground selection lines.

According to an implementation, an operation method of a memory device which includes a plurality of cell strings provided between a bit line and a common source line, the plurality of cell strings being respectively connected to a plurality of string selection lines and each of the plurality of cell strings being connected to a plurality of word lines and a plurality of ground selection lines includes selecting at least two ground selection lines among the plurality of ground selection lines, applying a program voltage simultaneously to the at least two ground selection lines, and applying a verify voltage simultaneously to the at least two ground selection lines.

According to an implementation, a memory device includes a plurality of first cell transistors that are connected in series between a first bit line and a common source line. The plurality of first cell transistors include a plurality of first string selection transistors, a plurality of first memory cells, and a plurality of first ground selection transistors. At least two ground selection transistors among the plurality of ground selection transistors are configured to have a first program state and remaining ground selection transistors among the plurality of ground selection transistors other than the at least two ground selection transistors are configured to have an erase state.

### BRIEF DESCRIPTION OF THE DRAWINGS

The above and other objects and features of the present disclosure will become apparent by describing in detail implementations thereof with reference to the accompanying drawings.

FIG. 1 is a block diagram illustrating a memory device according to implementations of the present disclosure.

FIG. 2 is a circuit diagram illustrating a first memory block included in a memory cell array of FIG. 1.

FIG. 3 is a plan view of a first memory block of FIG. 2.

FIGS. 4A and 4B are diagrams for describing a method of controlling a first memory block of FIGS. 2 and 3.

FIG. 5 is a flowchart illustrating an operation method of a memory device of FIG. 1.

FIG. 6 is a flowchart illustrating operation S120 of FIG. 5.

FIG. 7 is a diagram for describing an operation according to the flowchart of FIG. 6.

FIG. 8 is a flowchart illustrating operation S130 of FIG. 5.

FIG. 9 is a diagram for describing an operation according to the flowchart of FIG. 8.

FIG. 10 is a diagram for describing an operation of simultaneously programming 3a-th and 4a-th ground selection transistors of a first memory block of FIG. 9.

FIG. 11 illustrates threshold voltage distributions of ground selection transistors programmed according to the implementation of FIG. 10.

FIGS. 12A and 12B are diagrams for describing a GSL coding pattern according to an implementation of the present disclosure.

FIG. 13 is a diagram for describing a GSL coding pattern according to an implementation of the present disclosure.

FIGS. 14A and 14B are diagrams for describing a GSL coding pattern according to an implementation of the present disclosure.

FIGS. 15A and 15B are diagrams for describing a GSL coding pattern according to an implementation of the present disclosure.

FIGS. 16A and 16B are diagrams for describing a GSL coding pattern according to an implementation of the present disclosure.

FIGS. 17A and 17B are diagrams for describing a GSL coding pattern according to an implementation of the present disclosure.

FIG. 18 is a diagram for describing a GSL coding pattern according to an implementation of the present disclosure.

FIG. 19 is a diagram for describing a GSL coding pattern according to an implementation of the present disclosure.

FIG. 20 is a diagram for describing a GSL coding pattern according to an implementation of the present disclosure.

FIG. 21 is a diagram for describing a GSL coding pattern according to an implementation of the present disclosure.

FIGS. 22 and 23 are diagrams for describing a GSL coding pattern according to an implementation of the present disclosure.

FIG. 24 is a diagram for describing a memory device according to an implementation of the present disclosure.

FIG. 25 is a block diagram illustrating a memory system according to an implementation of the present disclosure.

### DETAILED DESCRIPTION

Below, implementations of the present disclosure will be described in detail and clearly to such an extent that an ordinary one in the art easily carries out the present disclosure.

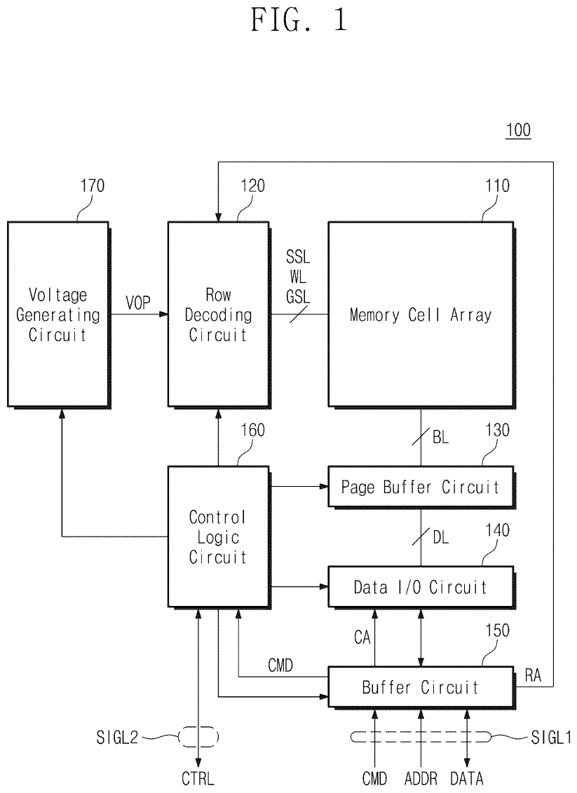

FIG. 1 is a block diagram illustrating a memory device according to implementations of the present disclosure. Referring to FIG. 1, a memory device 100 may include a memory cell array 110, a row decoding circuit 120, a page buffer circuit 130, a data input/output circuit 140, a buffer circuit 150, a control logic circuit 160, and a voltage generating circuit 170. In implementations, the memory device 100 may include a NAND flash memory device, but the present disclosure is not limited thereto.

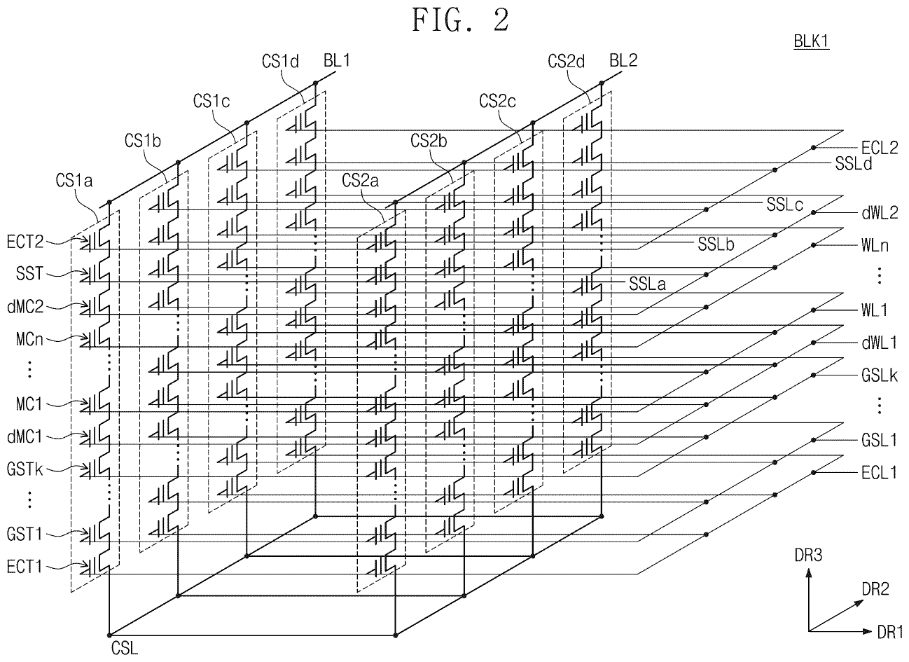

The memory cell array 110 may include a plurality of memory blocks. Each of the plurality of memory blocks may include a plurality of cell strings. Each of the plurality of cell strings may include a plurality of cell transistors stacked in a direction perpendicular to a substrate. The plurality of cell transistors may be connected in series between bit lines BL and a common source line. The plurality of cell transistors may be connected to string selection lines SSL, word lines WL, and ground selection lines GSL. The plurality of memory blocks will be described in detail with reference to FIG. 2.

The row decoding circuit 120 may be connected to the memory cell array 110 through the string selection lines SSL, the word lines WL, and the ground selection lines GSL. The row decoding circuit 120 may operate under control of the control logic circuit 160. For example, under control of the control logic circuit 160, the row decoding circuit 120 may decode a row address RA received from the buffer circuit 150; based on a decoding result, the row decoding circuit 120 may control or drive the string selection lines SSL, the word lines WL, and the ground selection lines GSL or may control voltages to be applied to the string selection lines SSL, the word lines WL, and the ground selection lines GSL.

The page buffer circuit 130 may be connected to the memory cell array 110 through the bit lines BL. The page buffer circuit 130 may be connected to the data input/output circuit 140 through a plurality of data lines DL. The page buffer circuit 130 may operate under control of the control logic circuit 160. For example, in the program operation of the memory device 100, the page buffer circuit 130 may store data to be programmed in the memory cell array 110 under control of the control logic circuit 160. In the read operation of the memory device 100, the page buffer circuit 130 may sense voltages of the bit lines BL and may store the sensed voltages as read data.

The data input/output circuit 140 may be connected to the page buffer circuit 130 through the plurality of data lines DL. The data input/output circuit 140 may receive a column address CA from the buffer circuit 150. The data input/output circuit 140 may transmit the data read by the page buffer circuit 130 to the buffer circuit 150 depending on the column address CA. The data input/output circuit 140 may transmit data received from the buffer circuit 150 to the page buffer circuit 130 based on the column address CA.

The buffer circuit 150 may receive a command CMD and an address ADDR from an external device (e.g., a controller) through first signal lines SIGL1 and may exchange data “DATA” with the external device (e.g., a controller) through the first signal lines SIGL1. In implementation, the first signal lines SIGL1 may include data signal lines (e.g., DQ lines) and a data strobe signal line (e.g., a DQS line).

The buffer circuit 150 may operate under control of the control logic circuit 160. For example, the control logic circuit 160 may exchange a control signal CTRL with the external device (e.g., a controller) through second signal lines SIGL2. The control logic circuit 160 may control the buffer circuit 150 based on the control signals CTRL such that the buffer circuit 150 routes the command CMD, the address ADDR, and the data “DATA”. Under control of the control logic circuit 160, the buffer circuit 150 may classify signals received through the first signal lines SIGL1 as the command CMD or the address ADDR. The buffer circuit 150 may transfer the command CMD to the control logic circuit 160. The buffer circuit 150 may transfer the row address RA of the address ADDR to the row decoding circuit 120 and may transfer the column address CA of the address ADDR to the data input/output circuit 140. The buffer circuit 150 may exchange the data “DATA” with the data input/output circuit 140.

The control logic circuit 160 may decode the command CMD received from the buffer circuit 150 and may control the memory device 100 or various components of the memory device 100 based on a decoding result.

Under control of the control logic circuit 160, the voltage generating circuit 170 may generate various operating voltages VOP which are used in the memory device 100. In implementations, the operating voltages VOP may include various voltages such as program voltages, pass voltages, selection read voltages, non-selection read voltages, erase voltages, and verify voltages. Below, various voltages which are used to describe implementations of the present disclosure may be include in the operating voltages VOP generated by the voltage generating circuit 170.

FIG. 2 is a circuit diagram illustrating a first memory block included in a memory cell array of FIG. 1. A structure of a first memory block BLK1 will be described with reference to FIG. 2, but the present disclosure is not limited thereto. For example, the memory cell array 110 may include a plurality of memory blocks, each of which is similar in structure to the first memory block BLK1 of FIG. 2.

In implementations, the first memory block BLK1 to be described with reference to FIG. 2 may correspond to a physical erase unit of the memory device 100. However, the present disclosure is not limited thereto. For example, the memory device 100 may perform the erase operation in units of page, word line, sub-block, or plane.

In implementations, the first memory block BLK1 to be described with reference to FIG. 2 is provided only as an example. The number of cell strings may increase or decrease, and the number of rows of cell strings and the number of columns of cell strings may increase or decrease depending on the number of cell strings. Also, the number of cell transistors GST, MC, dMC, SST, and ECT of the first memory block BLK1 may increase or decrease, and the height of the first memory block BLK1 may increase or decrease depending on the number of cell transistors. In addition, the number of lines GSL, WL, dWL, and SSL connected to the cell transistors may increase or decrease depending on the number of cell transistors.

Referring to FIGS. 1 and 2, the first memory block BLK1 may include a plurality of cell strings CS1a, CS1b, CS1c, CS1d, CS2a, CS2b, CS2c, and CS2d. The plurality of cell strings CS1a to CS2d may be disposed along a first direction DR1 and a second direction DR2 to form rows and columns.

The plurality cell strings CS1a to CS2d may be connected to bit lines BL1 and BL2. For example, each of the bit lines BL1 and BL2 may extend along the second direction DR2. The cell strings CS1a, CS1b, CS1c, and CS1d located at the same column, that is, the first column from among the plurality of cell strings CS1a to CS2d may be connected to the first bit line BL1, and the cell strings CS2a, CS2b, CS2c, and CS2d located at the same column, that is, the second column from among the plurality of cell strings CS1a to CS2d may be connected to the second bit line BL2.

The 1a-th cell string CS1a may include a plurality of cell transistors connected in series between the first bit line BL1 and a common source line CSL. The plurality of cell transistors of the 1a-th cell string CS1a located at the first column and first row may include a first erase control transistor ECT1, a plurality of ground selection transistors GST1 to GSTk, dummy memory cells dMC1 and dMC2, a plurality of memory cells MC1 to MCn, a string selection transistor SST, and a second erase control transistor ECT2. In implementations, each of the plurality of cell transistors may be implemented with a charge trap flash (CTF) memory cell.

The plurality of cell transistors of the 1a-th cell string CS1a may be connected in series and may be stacked in a third direction DR3 (or a height direction) which is a direction perpendicular to a plane defined by the first direction DR1 and the second direction DR2 or a substrate. For example, the plurality of memory cells MC1 to MCn may be connected in series and may be stacked in the third direction DR3 (or a height direction) being a direction perpendicular to the substrate. The string selection transistor SST may be provided between the plurality of memory cells MC1 to MCn and the first bit line BL1. The pluralality of ground selection transistors GST1 to GSTk may be connected in series and may be stacked in the third direction DR3 (or a height direction) being a direction perpendicular to the substrate. The plurality of ground selection transistors GST1 to GSTk connected in series may be provided between the plurality of memory cells MC1 to MCn connected in series and the common source line CSL.

In implementations, the first dummy memory cell dMC1 may be provided between the plurality of memory cells MC1 to MCn and the plurality of ground selection transistors GST1 to GSTk. In implementations, the second dummy memory cell dMC2 may be provided between the plurality of memory cells MC1 to MCn and the string selection transistor SST.

In implementations, the first erase control transistor ECT1 may be provided between the plurality of ground selection transistors GST1 to GSTk and the common source line CSL. The second erase control transistor ECT2 may be provided between the string selection transistor SST and the first bit line BL1. The first and second erase control transistors ECT1 and ECT2 may be used to charge the channel of the 1a-th cell string CS1a with an erase voltage or to erase the first memory block BLK1, based on a gate induced drain leakage (GIDL) phenomenon.

For convenience of description, the structure of the 1a-th cell string CS1a is described, but the present disclosure is not limited thereto. For example, each of the remaining cell strings CS1b to CS1d and CS2a to CS2d may be similar in structure to the 1a-th cell string CS1a.

The first erase control transistors ECT1 of the plurality of cell strings CS1a to CS2d may be connected in common to a first erase control line ECL1. The second erase control transistors ECT2 of the plurality of cell strings CS1a to CS2d may be connected in common to a second erase control line ECL2.

Memory cells located at the same height from the substrate from among the plurality of memory cells MC1 to MCn may be connected in common to the same word line, and memory cells located at another height from among the plurality of memory cells MC1 to MCn may be connected in common to another word line. For example, the first memory cells MC1 of the plurality of cell strings CS1a to CS2d may be located at the same height from the substrate and may be connected in common to a first word line WL1. The n-th memory cells MCn of the plurality of cell strings CS1a to CS2d may be located at the same height from the substrate and may be connected in common to an n-th word line WLn.

In implementations, the first dummy memory cells dMC1 of the plurality of cell strings CS1a to CS2d may be located at the same height from the substrate and may be connected in common to a first dummy word line dWL1. The second dummy memory cells dMC2 of the plurality of cell strings CS1a to CS2d may be located at the same height from the substrate and may be connected in common to a second dummy word line dWL2.

The string selection transistors SST of the plurality of cell strings CS1a to CS2d may be connected to a plurality of string selection lines SSLa to SSLd. For example, string selection transistors located at the same row may be connected to the same string selection line, and string selection transistors located at different rows may be connected to different string selection lines. In detail, the string selection transistors SST of the cell strings CS1a and CS2a located at the first row may be connected to an a-th string selection line SSLa; the string selection transistors SST of the cell strings CS1b and CS2b located at the second row may be connected to a b-th string selection line SSLb; the string selection transistors SST of the cell strings CS1c and CS2c located at the third row may be connected to a c-th string selection line SSLc; and, the string selection transistors SST of the cell strings CS1d and CS2d located at the fourth row may be connected to a d-th string selection line SSLd.

For brevity of drawing and for convenience, the description is given as each of the plurality of cell strings CS1a to CS2d includes one string selection transistor SST, but the present disclosure is not limited thereto. Each of the plurality of cell strings CS1a to CS2d may include a plurality of string selection transistors, and string selection transistors located at the same row from among string selection transistors located at the same height from the substrate may be connected to the same string selection line; in this case, string selection transistors located at different rows may be connected to different string selection lines.

Ground selection transistors located at the same height from the substrate may be connected to the same ground selection line. For example, first ground selection transistors GST1 of the plurality of cell strings CS1a to CS2d may be located at the same height from the substrate and may be connected in common to a first ground selection line GSL1. k-th ground selection transistors GSTk of the plurality of cell strings CS1a to CS2d may be located at the same height from the substrate and may be connected in common to a k-th ground selection line GSLk.

As illustrated in FIG. 2, the plurality of cell strings CS1a to CS2d may be connected in common to the ground selection lines GSL1 to GSLk or may share the ground selection lines GSL1 to GSLk. In this case, as the plurality of cell strings CS1a to CS2d are controlled by the same ground selection line, a ground selection transistor of an unselected cell string may be turned on during the read operation, the verify operation, or the channel recovery operation, thereby causing issues such as the reduction of reliability, the reduction of performance, and an increase in power consumption.

To solve the above issues, the ground selection transistors GST1 to GSKk of the plurality of cell strings CS1a to CS2d may be connected to a ground selection line in units of row such that the plurality of cell strings CS1a to CS2d are controlled individually or in units of row. In this case, a ground selection transistor of an unselected cell string may be turned off during the read operation, the verify operation, or the channel recovery operation, and thus, issues such as the reduction of reliability, the reduction of performance, and an increase in power consumption may be solved.

However, the physical limitations of the first memory block BLK1 may make it difficult to implement a structure in which the ground selection transistors GST1 to GSKk of the plurality of cell strings CS1a to CS2d are connected to a ground selection line in units of rows. In this case, the plurality of cell strings CS1a to CS2d may be individually controlled by individually setting a threshold voltage of each of the ground selection transistors GST1 to GSKk of the plurality of cell strings CS1a to CS2d and controlling voltages of the plurality of ground selection lines GSL1 to GSLk.

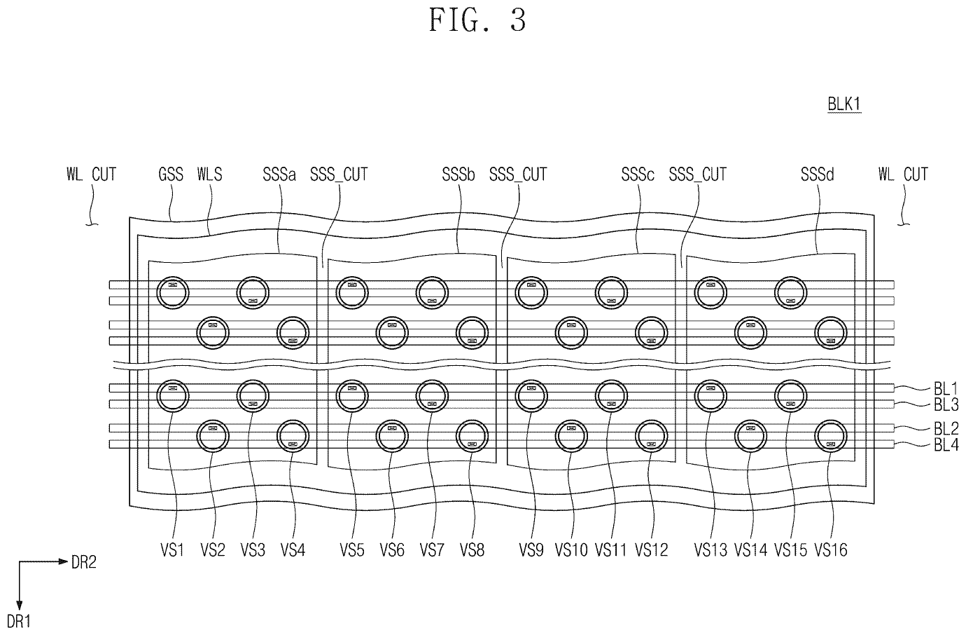

FIG. 3 is a plan view of a first memory block of FIG. 2. For convenience of description, some components of the first memory block BLK1 are omitted. However, the present disclosure is not limited thereto. Referring to FIGS. 2 and 3, the first memory block BLK1 may be formed on the substrate. The first memory block BLK1 may include a ground selection structure GSS, a word line structure WLS, and a plurality of string selection structures SSSa, SSSb, SSSc, and SSSd. The ground selection structure GSS, the word line structure WLS, and the plurality of string selection structures SSSa, SSSb, SSSc, and SSSd may be provided between word line cuts WL_CUT and may be stacked along a direction (e.g., the third direction DR3) perpendicular to the substrate defined by the first direction DR1 and the second direction DR2.

The plurality of string selection structures SSSa, SSSb, SSSc, and SSSd may extend along the first direction DR1 and may be electrically separated from each other by string selection cuts SSS_CUT. The first memory block BLK1 may include a plurality of vertical structures VS1 to VS16. The plurality of vertical structures VS1 to VS16 may penetrate the ground selection structure GSS, the word line structure WLS, and the plurality of string selection structures SSSa, SSSb, SSSc, and SSSd. For example, the first to fourth vertical structures VS1 to VS4 may penetrate the ground selection structure GSS, the word line structure WLS, and the a-th string selection structure SSSa; the fifth to eighth vertical structures VS5 to VS8 may penetrate the ground selection structure GSS, the word line structure WLS, and the b-th string selection structure SSSb; the ninth to twelfth vertical structures VS9 to VS12 may penetrate the ground selection structure GSS, the word line structure WLS, and the c-th string selection structure SSSca; and, the thirteenth to sixteenth vertical structures VS13 to VS16 may penetrate the ground selection structure GSS, the word line structure WLS, and the d-th string selection structure SSSd.

The plurality of vertical structures VS1 to VS16 may be connected to a plurality of bit lines BL1, BL2, BL3, and BL4 extending along the second direction DR2. For example, the first, fifth, ninth, and thirteenth vertical structures VS1, VS5, VS9, and VS13 may be connected to the first bit line BL1, the second, sixth, tenth, and fourteenth vertical structures VS2, VS6, VS10, and VS14 may be connected to the second bit line BL2, the third, seventh, eleventh, and fifteenth vertical structures VS3, VS7, VS11, and VS15 may be connected to the third bit line BL3, and the fourth, eighth, twelfth, and sixteenth vertical structures VS4, VS8, VS12, and VS16 may be connected to the fourth bit line BL4.

In implementations, each of the plurality of vertical structures VS1 to VS16 may form a cell string. For example, the first and second vertical structures VS1 and VS2 of FIG. 3 may respectively correspond to the 1a-th and 2a-th cell strings CS1a and CS2a of FIG. 2; the fifth and sixth vertical structures VS5 and VS6 of FIG. 3 may respectively correspond to the 1b-th and 2b-th cell strings CS1b and CS2b of FIG. 2; the ninth and tenth vertical structures VS9 and VS10 of FIG. 3 may respectively correspond to the 1c-th and 2c-th cell strings CS1c and CS2c of FIG. 2; and, the thirteenth and fourteenth vertical structures VS13 and VS14 of FIG. 3 may respectively correspond to the 1d-th and 2d-th cell strings CS1d and CS2d of FIG. 2.

In the structure of the first memory block BLK1 described with reference to FIG. 3, four string selection structures SSSa to SSSd may respectively correspond to four string selection lines SSLa to SSLd of FIG. 2. That is, in the first memory block BLK1 described with reference to FIG. 3, cell strings connected to four string selection lines SSLa to SSLd may share ground selection lines. Below, for convenience of description, an SSL-GSL structure of the first memory block BLK1 described with reference to FIGS. 2 and 3 may be referred to as a “4SSL-1GSL structure”. This may indicate a structure where cell strings connected to four string selection lines share one ground selection line.

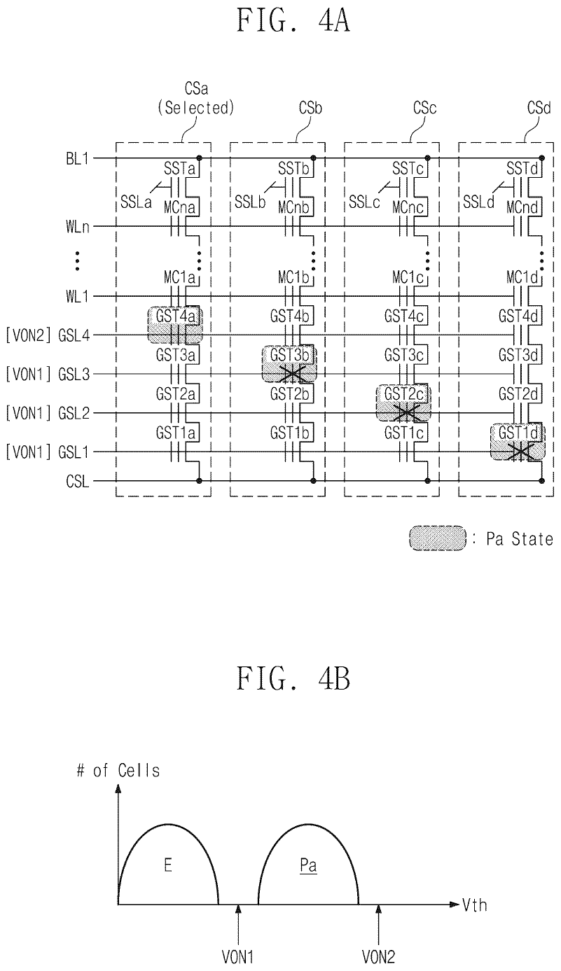

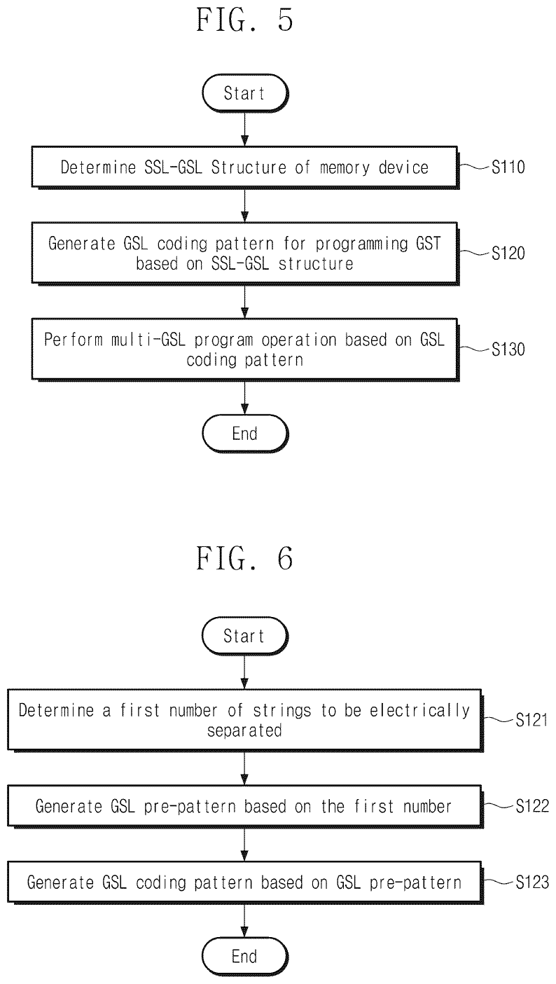

FIGS. 4A and 4B are diagrams for describing a method of controlling a first memory block of FIGS. 2 and 3. Below, for convenience of description, implementations of the present disclosure will be described based on a plurality of cell strings CSa, CSb, CSc, and CSd connected to the first bit line BL1. Also, some (e.g., dummy memory cells and an erase control transistor) of cell transistors included in each of the plurality of cell strings CSa, CSb, CSc, and CSd are omitted. However, the present disclosure is not limited thereto.

Below, for brevity of drawing and for convenience of description, some ground selection lines GSL and some ground selection transistors GST are illustrated in the drawing, but the present disclosure is not limited thereto. For example, in the following drawings, ground selection transistors or dummy ground selection transistors are illustrated as being directly connected to the common source line CSL, but additional ground selection transistors may further exist between the ground selection transistors or the dummy ground selection transistors and the common source line CSL.

Referring to FIGS. 1 to 4B, the first memory block BLK1 may include the a-th to d-th cell strings CSa to CSd. Each of the a-th to d-th cell strings CSa to CSd may be connected between the first bit line BL1 and the common source line CSL. The a-th cell string CSa may include a plurality of ground selection transistors GST1a to GST4a, a plurality of memory cells MC1a to MCna, and an a-th string selection transistor SSTa. The b-th cell string CSb may include a plurality of ground selection transistors GST1b to GST4b, a plurality of memory cells MC1b to MCnb, and a b-th string selection transistor SSTb. The c-th cell string CSc may include a plurality of ground selection transistors GST1c to GST4c, a plurality of memory cells MC1c to MCnc, and a c-th string selection transistor SSTc. The d-th cell string CSd may include a plurality of ground selection transistors GST1d to GST4d, a plurality of memory cells MC1d to MCnd, and a d-th string selection transistor SSTd.

The string selection transistors SSTa of the a-th cell string CSa may be connected to the a-th string selection line SSLa; the string selection transistors SSTb of the b-th cell string CSb may be connected to the b-th string selection line SSLb; the string selection transistors SSTc of the c-th cell string CSc may be connected to the c-th string selection line SSLc; and, the string selection transistors SSTd of the d-th cell string CSd may be connected to the d-th string selection line SSLd.

The ground selection transistors GST1a to GST4a, GST1b to GST4b, GST1c to GST4c, and GST1d to GST4d and the memory cells MC1a to MCna, MC1b to MCnb, MC1c to MCnc, and MC1d to MCnd of the a-th to d-th cell strings CSa to CSd may be connected to the plurality of ground selection lines GSL1 to GSL4 and the plurality of word lines WL1 to WLn. For example, the first memory cells MC1a, MC1b, MC1c, and MC1d of the a-th to d-th cell strings CSa to CSd may be connected to the first word line WL1, and the n-th memory cells MCna, MCnb, MCnc, and MCnd of the a-th to d-th cell strings CSa to CSd may be connected to the n-th word line WLn.

The ground selection transistors GST1a, GST1b, GST1c, and GST1d of the a-th to d-th cell strings CSa to CSd may be connected to the first ground selection line GSL1; the ground selection transistors GST2a, GST2b, GST2c, and GST2d of the a-th to d-th cell strings CSa to CSd may be connected to the second ground selection line GSL2; the ground selection transistors GST3a, GST3b, GST3c, and GST3d of the a-th to d-th cell strings CSa to CSd may be connected to the third ground selection line GSL3; and, the ground selection transistors GST4a, GST4b, GST4c, and GST4d of the a-th to d-th cell strings CSa to CSd may be connected to the fourth ground selection line GSL4.

In implementations, while the memory device 100 operates, one of the plurality of cell strings CSa to CSd may be selected, and the remaining cell strings may not be selected. In this case, a threshold voltage of each of the plurality of ground selection transistors GST1a to GST4d may be set such that the remaining unselected cell strings among the plurality of cell strings CSa to CSd other than the selected cell string are not electrically connected to the common source line CSL.

For example, as illustrated in FIG. 4B, a threshold voltage or a threshold voltage distribution of an a-th program state Pa may be higher than a threshold voltage or a threshold voltage distribution of an erase state “E”. In this case, a ground selection transistor having the a-th program state Pa may be turned off by a first on-voltage VON1 and may be turned on by a second on-voltage VON2. In implementations, the erase state “E” may indicate a threshold voltage distribution different from the a-th program state Pa. In implementations, the erase state “E” may indicate a threshold voltage distribution lower than that of the a-th program state Pa. For example, threshold voltages of ground selection transistors corresponding to the erase state “E” may be lower than threshold voltages of ground selection transistors corresponding to the a-th program state Pa. In implementations, the threshold voltages of the ground selection transistors corresponding to the erase state “E” may be different from threshold voltages of memory cells MC corresponding the erase state “E”.

The threshold voltages of 4a-th, 3b-th, 2c-th, and 1d-th ground selection transistors GST4a, GST3b, GST2c, and GST1d among the plurality of ground selection transistors GST1a to GST4a may be set to the a-th program state Pa. In this case, as the first on-voltage VON1 or the second on-voltage VON2 is applied to each of the plurality of ground selection lines GSL1 to GSL4, the remaining unselected cell strings among the plurality of cell strings CSa to CSd other than the selected cell string may not be electrically connected to the common source line CSL.

In detail, it is assumed that the a-th cell string CSa is a selected cell string. In this case, the first on-voltage VON1 may be applied to the first to third ground selection line lines GSL1 to GSL3, and the second on-voltage VON2 may be applied to the fourth ground selection lines GSL4. As the first on-voltage VON1 is applied to the first ground selection line GSL1, the 1a-th, 1b-th, and 1c-th ground selection transistors GST1a, GST1b, and GST1c may be turned on, and the ground selection transistor GST1d may be turned off. As the first on-voltage VON1 is applied to the second ground selection line GSL2, the 2a-th, 2b-th, and 2d-th ground selection transistors GST2a, GST2b, and GST2d may be turned on, and the ground selection transistor GST2c may be turned off. As the first on-voltage VON1 is applied to the third ground selection line GSL3, the 3a-th, 3c-th, and 3d-th ground selection transistors GST3a, GST3c, and GST3d may be turned on, and the ground selection transistor GST3b may be turned off. As the second on-voltage VON2 is applied to the fourth ground selection line GSL4, the ground selection transistors GST4a, GST4b, GST4c, and GST4d connected to the fourth ground selection line GSL4 may be turned on.

That is, according to the above bias condition associated with the ground selection lines GSL1 to GSL4, because all the ground selection transistors GST1a to GST4a of the a-th cell string CSa being the selected cell string are turned on, the a-th cell string CSa may be electrically connected to the common source line CSL. In contrast, because the 3b-th, 2c-th, and 1d-th ground selection transistors GST3b, GST2c, and GST1d are turned off, the b-th, c-th, and d-th cell strings CSb, CSc, and CSd being the unselected cell strings may be electrically separated from the common source line CSL. Accordingly, issues, which may occur during the operation of the memory device 100, such as the reduction of reliability, the reduction of performance, and an increase in power consumption may be prevented.

In implementations, the program operation associated with the ground selection lines GSL1 to GSLA may be performed to set the ground selection transistors GST4a, GST3b, GST2c, and GST1d to threshold voltages of the a-th program state Pa. For example, the threshold voltage of the 4a-th ground selection transistor GST4a may be set to the a-th program state Pa by applying the program voltage to the fourth ground selection line GSL4 and applying the pass voltage to the remaining lines (e.g., GSL1 to GSL3 and WL1 to WLn). The threshold voltage of the 3b-th ground selection transistor GST3b may be set to the a-th program state Pa by applying the program voltage to the third ground selection line GSL3 and applying the pass voltage to the remaining lines (e.g., GSL1, GSL2, GSL4, and WL1 to WLn). The threshold voltage of the 2c-th ground selection transistor GST2c may be set to the a-th program state Pa by applying the program voltage to the second ground selection line GSL2 and applying the pass voltage to the remaining lines (e.g., GSL1, GSL3, GSL4, and WL1 to WLn). The threshold voltage of the 1d-th ground selection transistor GST1d may be set to the a-th program state Pa by applying the program voltage to the first ground selection line GSL1 and applying the pass voltage to the remaining lines (e.g., GSL2, GSL3, GSL4, and WL1 to WLn).

In implementations, the threshold voltages of the ground selection transistors GST1a to GST4d may be changed due to various factors. For example, as the memory device 100 operates, the threshold voltages of the ground selection transistors GST1a to GST4d may decrease depending on a retention characteristic of the ground selection transistors GST1a to GST4d. Alternatively, as the memory device 100 operates, the read disturbance may occur in the ground selection transistors GST1a to GST4d, thereby causing the increase in the threshold voltages of the ground selection transistors GST1a to GST4d. Alternatively, as the memory device 100 operates, a hot electron injection phenomenon may occur in the ground selection transistors GST1a to GST4d, thereby causing the increase in the threshold voltages of the ground selection transistors GST1a to GST4d.

As described above, as the threshold voltages of the ground selection transistors GST1a to GST4d are changed, the memory device 100 may not operate normally, thereby causing the reduction of performance and the reduction of reliability in the memory device 100.

FIG. 5 is a flowchart illustrating an operation method of a memory device of FIG. 1. Below, for convenience of description, implementations of the present disclosure will be described based on the operation method of the memory device 100. However, the present disclosure is not limited thereto. For example, an operation according to the flowchart of FIG. 5 may be performed in the process of manufacturing or testing the memory device 100. That is, in the process of manufacturing or testing the memory device 100, the setting of threshold voltages of a plurality of ground selection transistors of the memory device 100 may be performed. Alternatively, during the operation of the memory device 100, the memory device 100 may perform the operation according to the flowchart of FIG. 5.

Referring to FIGS. 1 and 5, in operation S110, the memory device 100 may determine the SSL-GSL structure of the memory device 100. For example, the memory device 100 may include a plurality of memory blocks, which are formed based on one of various structures. As an example, as described with reference to FIGS. 2 and 3, each of the plurality of the memory blocks of the memory device 100 may be formed based on the 4SSL-1GSL structure. The structure of the 4SSL-1GSL structure is described with reference to FIGS. 2 and 3, and thus, additional description will be omitted to avoid redundancy.

In operation S120, the memory device 100 may generate a GSL coding pattern for programming the ground selection transistors based on the SSL-GSL structure. For example, as described with reference to FIGS. 4A and 4B, in the first memory block BLK1 with the 4SSL-1GSL structure, some ground selection transistors GST4a, GST3b, GST2c, and GST1d may be programmed to the a-th program state such that unselected cell strings are not electrically connected to the common source line CSL. In this case, the cell strings CSa, CSb, CSc, and CSd may be individually controlled by controlling levels of the plurality of ground selection lines GSL1 to GSL4. However, as described with reference to FIGS. 4A and 4B, threshold voltages of ground selection transistors may be changed due to various factors; in this case, the reliability and performance of operation of the memory device 100 may be reduced.

The GSL coding pattern according to implementations of the present disclosure may be set such that at least two ground selection transistors have the same threshold voltage state. In this case, the change in the threshold voltages of the ground selection transistors may be prevented or minimized, and thus, the reduction of reliability and performance of operation of the memory device 100 may be prevented. In implementations, that ground selection transistors are adjacent to each other may mean that the ground selection transistors are directly connected. Alternatively, that ground selection transistors are adjacent to each other may mean that any other dummy ground selection transistor does not exist between the adjacent ground selection transistors.

The GSL coding patterns according to implementations of the present disclosure will be described in detail with reference to the following drawings.

In operation S130, the memory device 100 may perform a multi-GSL program operation based on the GSL coding pattern. For example, the memory device 100 may simultaneously program at least two adjacent ground selection transistors by simultaneously applying the program voltage to at least two adjacent ground selection lines based on the GSL coding pattern. The multi-GSL program operation in operation S130 will be described in detail with reference to the following drawings.

As described above, according to an implementations of the present disclosure, because at least two adjacent ground selection transistors have the same threshold voltage state, the change in the threshold voltages of the ground selection transistors may be prevented or minimized. That is, the reduction of reliability and reduced performance of operation of the memory device 100 may be prevented.

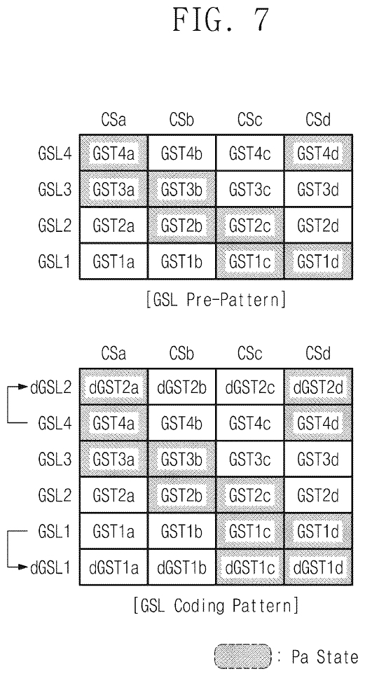

FIG. 6 is a flowchart illustrating operation S120 of FIG. 5. FIG. 7 is a diagram for describing an operation according to the flowchart of FIG. 6.

Below, for convenience of description, implementations of the present disclosure will be described based on the cell strings CSa, CSb, CSc, and CSd connected to the first bit line BL1, but the present disclosure is not limited thereto. For example, it may be understood that implementations of the present disclosure are applicable to a plurality of cell strings respectively connected to the plurality of bit lines BL. As an example, the a-th cell string CSa may indicate a cell string which is connected to the first bit line BL1 and is connected to the a-th string selection line SSLa, but it may be understood that the a-th cell string CSa indicates any other cell strings connected to the a-th string selection line SSLa and any other bit lines or is capable of being replaced therewith.

Referring to FIGS. 1, 6, and 7, in operation S121, the memory device 100 may determine the first number of strings to be electrically separated. For example, as described with reference to FIGS. 2 and 3, the first memory block BLK1 may have the 4SSL-1GSL structure. In this case, the electrical separation of four cell strings of the first memory block BLK1 may be required. In this case, the first number may be “4”.

In operation S122, the memory device 100 may generate a GSL pre-pattern based on the first number. Below, for convenience of description, it is assumed that when a ground selection transistor is set to have one of the erase state “E” or the a-th program state Pa, a bit pattern of “0” indicates that a ground selection transistor corresponding to the bit pattern of “0” is in the erase state “E” and a bit pattern of “1” indicates that a ground selection transistor corresponding to the bit pattern of “1” is in the a-th program state Pa. That is, when a pattern corresponding to the ground selection transistors GST1a, GST2a, GST3a, and GST4a connected to a first ground

selection line is [0011], it may mean that the 1a-th ground selection transistor GST1a is in the erase state “E”, the 2a-th ground selection transistor GST2a is in the erase state “E”, the 3a-th ground selection transistor GST3a is in the a-th program state Pa, and the 4a-th ground selection transistor GST4a is in the a-th program state Pa. This is provided for describing implementations of the present disclosure easily and briefly, but the present disclosure is not limited thereto.

In implementations, as described above, the electrical separation of four cell strings of the first memory block BLK1 may be required. In this case, the GSL pre-pattern for four ground selection lines may be generated. In this case, the GSL pre-pattern may be generated such that at least two adjacent ground selection transistors have the same threshold voltage state.

The expression “adjacent ground selection transistors” or that ground selection transistor are adjacent to each other may mean ground selection transistors physically adjacent to each other and connected in series from among ground selection transistors included in the same cell string. For example, the a-th cell string CSa may include ground selection transistors GST1a, GST2a, GST3a, and GST4a connected in series. In this case, the 1a-th and 2a-th ground selection transistors GST1a and GST2a may be ground selection transistors adjacent to each other. Alternatively, the 3a-th and 4a-th ground selection transistors GST3a and GST4a may be ground selection transistors adjacent to each other. However, the present disclosure is not limited thereto.

In implementations, as illustrated in FIG. 7, when the a-th to d-th cell strings CSa, CSb, CSc, and CSd sharing a ground selection line are electrically distinguished from each other, GSL pre-patterns for the first to fourth ground selection lines GSL1 to GSL4 may be respectively determined as [0011], [0110], [1100], and [1001].

As an example, that the GSL pre-pattern for the first ground selection line GSL1 is may mean that, through the multi-GSL program operation, the 1a-th ground selection transistor GST1a is programmed to have the erase state “E”, the 1b-th ground selection transistor GST1b is programmed to have the erase state “E”, the 1c-th ground selection transistor GST1c is programmed to have the a-th program state Pa, and the 1d-th ground selection transistor GST1d is programmed to have the a-th program state Pa. That the GSL pre-pattern for the second ground selection line GSL2 is may mean that, through the multi-GSL program operation, the 2a-th ground selection transistor GST2a is programmed to have the erase state “E”, the 2b-th ground selection transistor GST2b is programmed to have the a-th program state Pa, the 2c-th ground selection transistor GST2c is programmed to have the a-th program state Pa, and the 2d-th ground selection transistor GST2d is programmed to have the erase state “E”. That the GSL pre-pattern for the first ground selection line GSL3 is may mean that, through the multi-GSL program operation, the 3a-th ground selection transistor GST3a is programmed to have the a-th program state Pa, the 3b-th ground selection transistor GST3b is programmed to have the a-th program state Pa, the 3c-th ground selection transistor GST3c is programmed to have the erase state “E”, and the 3d-th ground selection transistor GST3d is programmed to have the erase state “E”. That the GSL pre-pattern for the fourth ground selection line GSL4 is may mean that, through the multi-GSL program operation, the 4a-th ground selection transistor GST4a is programmed to have the a-th program state Pa, the 4b-th ground selection transistor GST4b is programmed to have the erase state “E”, the 4c-th ground selection transistor GST4c is programmed to have the erase state “E”, and the 4d-th ground selection transistor GST4d is programmed to have the a-th program state Pa.

In operation S123, the memory device 100 may perform the GSL coding pattern based on the GSL pre-pattern. For example, as illustrated in FIG. 7, the GSL pre-patterns for the first to fourth ground selection lines GSL1 to GSL4 may be respectively determined as [0011], [0110], [1100], and [1001].

In this case, a first dummy ground selection line dGSL1 which is located between the first ground selection line GSL1 and the substrate may be provided. The GSL pre-pattern of the first dummy ground selection line dGSL1 may correspond to the GSL pre-pattern of the first ground selection line GSL1. That is, the first dummy ground selection line dGSL1 may correspond to the pattern of [0011]. As in the above description, a second dummy ground selection line dGSL2 may be provided between the fourth ground selection line GSL4 and word lines (e.g., WL1 to WLn). The GSL pre-pattern of the second dummy ground selection line dGSL2 may correspond to the GSL pre-pattern of the fourth ground selection line GSL4. That is, the second dummy ground selection line dGSL2 may correspond to the pattern of [1001].

In this case, the GSL coding pattern may include patterns of [0011], [0011], [0110], [1100], [1001], and [1001] which respectively correspond to the first dummy ground selection line dGSL1, the first to fourth ground selection lines GSL1 to GSL4, and the second dummy ground selection line dGSL2.

When the GSL coding pattern is generated as illustrated in FIG. 7, in each of the cell strings CSa to CSd, at least two adjacent ground selection transistors may have the same state. For example, in the a-th cell string CSa, the 3a-th and 4a-th ground selection transistors GST3a and GST4a and a 2a-th dummy ground selection transistor dGST2a may be ground selection transistors adjacent to each other and may have the same program state, that is, the a-th program state Pa. In the b-th cell string CSb, the 2b-th and 3b-th ground selection transistors GST2b and GST3b may be ground selection transistors adjacent to each other and may have the same program state, that is, the a-th program state Pa. In the c-th cell string CSc, the 1c-th and 2c-th ground selection transistors GST1c and GST2c and a 1c-th dummy ground selection transistor dGST1c may be ground selection transistors adjacent to each other and may have the same program state, that is, the a-th program state Pa. In the d-th cell string CSd, the 1d-th ground selection transistor GST1d and a 1d-th dummy ground selection transistor dGST1d may be ground selection transistors adjacent to each other and have the same program state, that is, the a-th program state Pa, and the 4d-th ground selection transistor GST4d and the 2d-th dummy ground selection transistor dGST2d may be ground selection transistors adjacent to each other and have the same program state, that is, the a-th program state Pa. That is, through the GSL coding pattern described above, in each cell string, at least two adjacent ground selection transistors may have the same state.

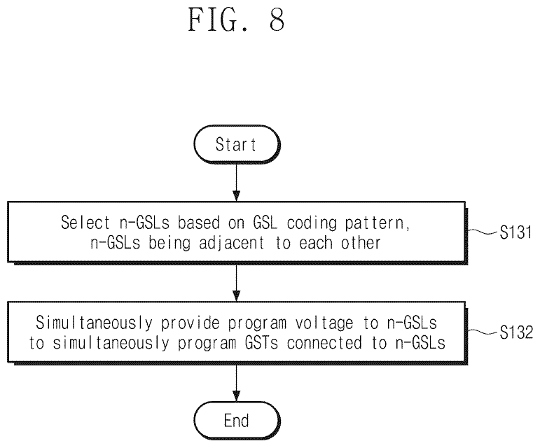

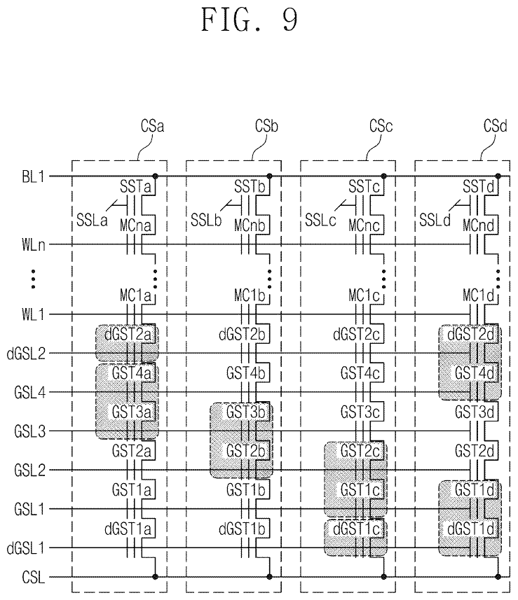

FIG. 8 is a flowchart illustrating operation S130 of FIG. 5. FIG. 9 is a diagram for describing an operation according to the flowchart of FIG. 8. For convenience of description, additional description associated with the components described above will be omitted to avoid redundancy.

Referring to FIGS. 1, 8, and 9, in operation S131, the memory device 100 may select “n” ground selection lines based on the GSL coding pattern (n being a natural number of 2 or more). In implementations, the “n” ground selection lines may be ground selection lines adjacent to each other.

For example, it is assumed that the GSL coding pattern is the pattern described with reference to FIG. 7. That is, the GSL coding pattern may include patterns of [0011], [0011], [0110], [1100], [1001], and [1001] which respectively correspond to the first dummy ground selection line dGSL1, the first to fourth ground selection lines GSL1 to GSL4, and the second dummy ground selection line dGSL2.

The memory device 100 may perform the multi-GSL program operation on the ground selection transistors GST1a, GST2a, GST3a, and GST4a and the dummy ground selection transistors dGST1a and dGST2a of the a-th cell string CSa. According to the GSL coding pattern, the 3a-th and 4a-th ground selection transistors GST3a and GST4a and the 2a-th dummy ground selection transistor dGST2a of the a-th cell string CSa may be programmed to the a-th program state Pa. In this case, the third and fourth ground selection lines GSL3 and GSL4 connected to ground selection transistors (e.g., GST3a and GST4a) to be programmed to the a-th program state Pa may be selected.

In implementations, when the GSL pre-pattern is generated based on two adjacent ground selection transistors, two ground selection lines connected to the adjacent ground selection transistors corresponding to the same state may be selected. In implementations, when a dummy ground selection line is included in the ground selection lines connected to the adjacent ground selection transistors corresponding to the same state, two of ground selection lines other than the dummy ground selection line may be selected. However, the present disclosure is not limited thereto. For example, the number of ground selection lines to be selected for the multi-GSL program operation may be variously changed and modified, which will be described in detail through the following implementations.

In operation S132, the memory device 100 may simultaneously apply the program voltage to the selected “n” ground selection lines such that ground selection transistors connected to the selected “n” ground selection lines are simultaneously programmed. For example, as illustrated in FIG. 9, the third and fourth ground selection lines GSL3 and GSL4 may be selected to program the ground selection transistors GST3a and GST4a of the a-th cell string CSa to the a-th program state Pa. The memory device 100 may simultaneously apply the program voltage to the third and fourth ground selection lines GSL3 and GSL4 and may apply the pass voltage to the remaining lines (e.g., dGSL1, GSL1, GSL2, dGSL2, and WL1 to WLn). Also, a power supply voltage (e.g., VCC) may be applied to the a-th string selection line SSLa connected to the a-th string selection transistor SSTa of the a-th cell string CSa being the selected cell string, and a turn-off voltage (e.g., a ground voltage) may be applied to the remaining string selection lines SSLb, SSLc, and SSLd. In this case, the 3a-th and 4a-th ground selection transistors GST3a and GST4a of the a-th cell string CSa may be simultaneously programmed.

In implementations, the multi-GSL program operation in which the 3a-th and 4a-th ground selection transistors GST3a and GST4a are simultaneously programmed may be performed based on an incremental step programming pulse (ISPP) manner. For example, after the program voltage is applied to the third and fourth ground selection lines GSL3 and GSL4, the 3a-th and 4a-th ground selection transistors GST3a and GST4a may be verified by applying the verify voltage to the third and fourth ground selection lines GSL3 and GSL4. When a result of verifying the program state of the 3a-th and 4a-th ground selection transistors GST3a and GST4a indicates a failure, a higher program voltage may be applied to the third and fourth ground selection lines GSL3 and GSL4, and then, the verify voltage may be applied to the third and fourth ground selection lines GSL3 and GSL4.

In implementations, the memory device 100 may set threshold voltages of ground selection transistors of the first memory block BLK1 by repeatedly performing operation S131 and operation S132 based on the GSL coding pattern.

For example, as illustrated in FIG. 9, the memory device 100 may simultaneously program the 3a-th and 4a-th ground selection transistors GST3a and GST4a of the a-th cell string CSa. The memory device 100 may program the 2a-th dummy ground selection transistor dGST2a of the a-th cell string CSa. The memory device 100 may simultaneously program the 2b-th and 3b-th ground selection transistors GST2b and GST3b of the b-th cell string CSb. The memory device 100 may simultaneously program the 1c-th and 2c-th ground selection transistor GST1c and GST2c of the c-th cell string CSc. The memory device 100 may program the 1c-th dummy ground selection transistor dGST1c. The memory device 100 may simultaneously program the 1d-th dummy ground selection transistor dGST1d and the 1d-th ground selection transistor GST1d of the d-th cell string CSd. The memory device 100 may simultaneously program the 4d-th ground selection transistor GST4d and the 2d-th dummy ground selection transistor dGST2d. In implementations, the above program order is provided as an example, and the present disclosure is not limited thereto.

As described above, the GSL coding pattern may be generated such that adjacent ground selection transistors have the same state (e.g., an a-th program state). The memory device 100 may simultaneously program at least two adjacent ground selection transistors based on the GSL coding pattern.

In implementations, at least two adjacent ground selection transistors may include a dummy ground selection transistor. In this case, when the number of remaining ground selection transistors among the at least two adjacent ground selection transistors other than the dummy ground selection transistor is a multiple of the given number (e.g., 2 or more), the memory device 100 may simultaneously program the remaining ground selection transistors and may individually program the dummy ground selection transistor. Alternatively, when the number of at least two adjacent ground selection transistors including a dummy ground selection transistor is a multiple of the given number (e.g., 2 or more), the memory device 100 may simultaneously program the at least two adjacent ground selection transistors including the dummy ground selection transistor.

According to the above implementations, ground selection transistors targeted for the a-th program state Pa from among ground selection transistors (e.g., GST1a to GST4a, GST1b to GST4b, GST1c to GST4c, and GST1d to GST4d) to be used to control a cell string individually are simultaneously programmed together with an adjacent ground selection transistor or an adjacent dummy ground selection transistor. For example, the 3a-th and 4a-th ground selection transistors GST3a and GST4a of the a-th cell string CSa are simultaneously programmed; the 2b-th and 3b-th ground selection transistors GST2b and GST3b of the b-th cell string CSb are simultaneously programmed; the 1c-th and 2c-th ground selection transistors GST1c and GST2c of the c-th cell string CSc are simultaneously programmed. Also, in the d-th cell string CSd, the 1d-th ground selection transistor GST1d is simultaneously programmed together with the 1d-th dummy ground selection transistor dGST1d, and the 4d-th ground selection transistor GST4d is simultaneously programmed together with the 2d-th dummy ground selection transistor dGST2d. In this case, a cell characteristic of ground selection transistors (e.g., GST1a to GST4a, GST1b to GST4b, GST1c to GST4c, and GST1d to GST4d) to be used to control a cell string individually may be improved. For example, a retention characteristic of the ground selection transistors may be improved, the ground selection transistors may be strengthened against a read disturbance, and hot electron injection in the ground selection transistors may be reduced. Accordingly, the reliability and performance of the memory device 100 may be improved.

In implementations, to select a specific cell string during the operation of the memory device 100, the same bias may be provided to at least two adjacent ground selection lines based on the GSL coding pattern.

For example, when the a-th cell string CSa is selected, the second on-voltage VON2 may be applied to the third and fourth ground selection lines GSL3 and GSL4, the first on-voltage VON1 may be applied to the first and second ground selection line lines GSL1 and GSL2, and the second on-voltage VON2 may be applied to the first and second dummy ground selection lines dGSL1 and dGSL2. In this case, the ground selection transistors GST1a to GST4a of the a-th cell string CSa are turned on, the 2b-th ground selection transistor GST2b of the b-th cell string CSb is turned off, the 1c-th and 2c-th ground selection transistors GST1c and GST2c of the c-th cell string CSc are turned off, and the 1d-th ground selection transistor GST1d of the d-th cell string CSd is turned off. Accordingly, the remaining cell strings CSb, CSc, and CSd other than the a-th cell string CSa may be electrically separated from the common source line CSL.

As in the above description, when the b-th cell string CSb is selected, the second on-voltage VON2 may be applied to the second and third ground selection lines GSL2 and GSL3, the first on-voltage VON1 may be applied to the first and fourth ground selection line lines GSL1 and GLS4, and the second on-voltage VON2 may be applied to the first and second dummy ground selection lines dGSL1 and dGSL2. In this case, the ground selection transistors GST1b to GST4b of the b-th cell string CSb are turned on, the 4a-th ground selection transistor GST4a of the a-th cell string CSa is turned off, and the 1c-th ground selection transistor GST1c of the c-th cell string CSc is turned off, and the 1d-th the 4d-th ground selection transistors GST1d and GST4d of the d-th cell string CSd are turned off. Accordingly, the remaining cell strings CSa, CSc, and CSd other than the b-th cell string CSb may be electrically separated from the common source line CSL.

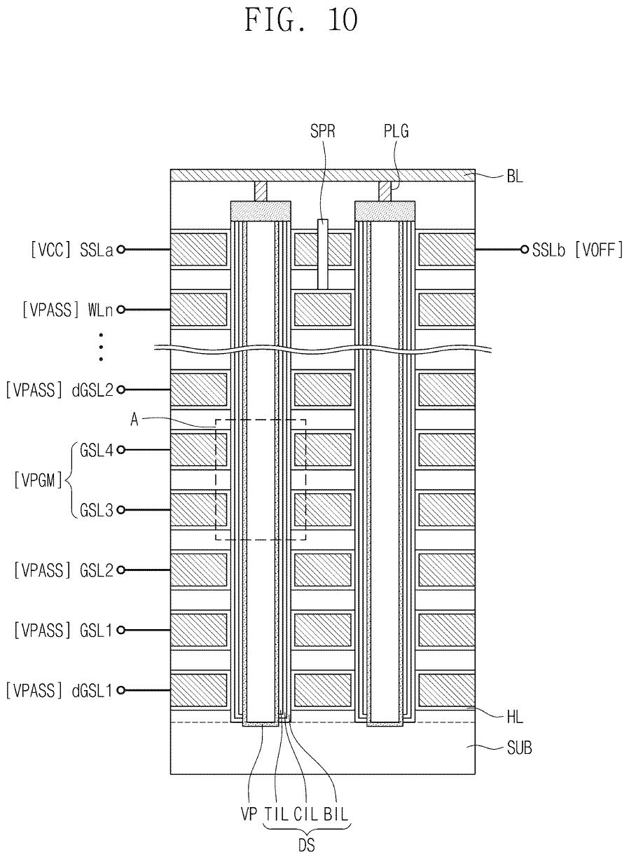

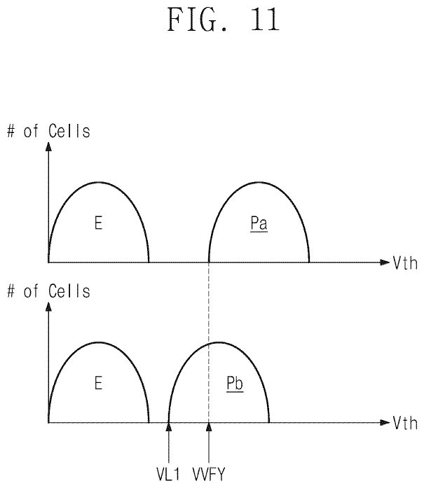

FIG. 10 is a diagram for describing an operation of simultaneously programming 3a-th and 4a-th ground selection transistors of a first memory block of FIG. 9. FIG. 11 illustrates threshold voltage distributions of ground selection transistors programmed according to the implementations of FIG. 10.

In implementations, FIG. 10 is a vertical cross-sectional view illustrating the a-th cell string CSa and the b-th cell string CSb. For convenience of description, some components are omitted. However, the present disclosure is not limited thereto.

Referring to FIGS. 1, 8, 9, 10, and 11, the first dummy ground selection line dGSL1, the first to fourth ground selection lines GSL1 to GSL4, the word lines WL1 to WLn, and the string selection lines SSLa and SSLb may be stacked on a substrate SUB.

A horizontal insulating pattern HL may be formed to extend along an upper surface, a lower surface, and a side wall (or side surface) of each of the first dummy ground selection line dGSL1, the first to fourth ground selection lines GSL1 to GSL4, the word lines WL1 to WLn, and the string selection lines SSLa and SSLb. In implementations, the horizontal insulating pattern HL may form a portion of a data storage layer storing data. The horizontal insulating pattern HL may be implemented with one of high-k dielectric layers such as a silicon oxide layer and a hafnium oxide layer and may be formed of a material whose dielectric constant is smaller than that of a blocking insulating layer BIL. The a-th string selection line SSLa and the b-th string selection line SSLb may be electrically separated from each other by a separation insulating pattern SPR.

A plurality of vertical structures (e.g., VS (refer to FIG. 3)) may be formed to extend through the first dummy ground selection line dGSL1, the first to fourth ground selection lines GSL1 to GSL4, the word lines WL1 to WLn, and the string selection lines SSLa and SSLb in a direction perpendicular to the substrate SUB. Each of the plurality of vertical structures (e.g., VS (refer to FIG. 3)) may include a vertical pattern VP and data storage pattern DS.

The vertical pattern VP may include a semiconductor material and may be used as a channel of cell transistors (e.g., GST, MC, and SST) included in each of the a-th and b-th cell strings CSa and CSb.

The data storage pattern DS may be provided to surround the vertical pattern VP and may include a charge storage layer configured to store data. For example, the data storage pattern DS may include a tunnel insulating layer TIL, a charge storage layer CIL, and the blocking insulating layer BIL. The charge storage layer CIL may be one of insulating layers in which there are a lot of trap sites and insulating layers including nano particles. For example, the charge storage layer CIL may include one of a trap insulating layer, a floating gate electrode, or an insulating layer including conductive nano dots.

In implementations, the data storage pattern DS may extend in a direction perpendicular to the substrate SUB while crossing the side walls of the first dummy ground selection line dGSL1, the first to fourth ground selection lines GSL1 to GSL4, the second dummy ground selection line dGSL2, the word lines WL1 to WLn, and the string selection lines SSLa and SSLb. The bit line BL may be formed on the vertical structures and may be electrically connected to the vertical structures through contact plugs PLG.

The above cross-sectional structure of the first memory block BLK1 is provided as an example, and the present disclosure is not limited thereto.

In implementations, the vertical structure penetrating the a-th string selection line SSLa is the a-th cell string CSa. In this case, the first dummy ground selection line dGSL1 and the data storage pattern DS and the vertical pattern VS adjacent thereto may constitute the 1a-th dummy ground selection transistor dGST1a; the first to fourth ground selection lines GSL1 to GSL4 and the data storage pattern DS and the vertical pattern VS adjacent thereto may constitute the 1a-th to 4a-th ground selection transistors GST1a to GST4a, respectively; the second dummy ground selection line dGSL2 and the data storage pattern DS and the vertical pattern VS adjacent thereto may constitute the 2a-th dummy ground selection transistor dGST2a; the first to n-th word lines WL1 to WLn and the data storage pattern DS and the vertical pattern VS adjacent thereto may constitute the first to n-th memory cells MC1 to MCn, respectively; and, the a-th string selection line SSLa and the data storage pattern DS and the vertical pattern VS adjacent thereto may constitute the a-th string selection transistor SSTa.

In this case, charges may be trapped in the data storage pattern DS corresponding to each cell transistor by a voltage applied to each line. This may mean that the threshold voltage of each cell transistor is changed.

According to implementations of the present disclosure, at least two adjacent ground selection transistors are simultaneously programmed. For example, as illustrated in FIG. 10, the 3a-th and 4a-th ground selection transistors GST3a and GST4a of the a-th cell string CSa may be simultaneously programmed. In this case, the power supply voltage VCC may be applied to the a-th string selection line SSLa; an off-voltage VOFF (e.g., a ground voltage or a negative voltage) may be applied to the b-th string selection line SSLb; a pass voltage VPASS may be applied to the plurality of word lines WL1 to WLn, the first and second dummy ground selection lines dGSL1 and dGSL2, and the first and second ground selection line lines GSL1 and GSL2; and a program voltage VPGM may be applied to the third and fourth ground selection lines GSL3 and GSL4. According to the above bias condition, charges may be trapped in the data storage pattern DS adjacent to the third and fourth ground selection lines GSL3 and GSL4. That is, the 3a-th and 4a-th ground selection transistors GST3a and GST4a may be programmed. Alternatively, the threshold voltages of the 3a-th and 4a-th ground selection transistors GST3a and GST4a may increase.

In this case, the cell characteristic of the 3a-th and 4a-th ground selection transistors GST3a and GST4a may be improved. For example, a threshold voltage of a cell transistor may be determined by charges trapped in a data storage pattern corresponding to the cell transistor. The charges trapped in the data storage pattern may be spread to any other region adjacent thereto over time. In this case, the threshold voltage of the corresponding cell transistor may decrease. In contrast, the threshold voltages of the 3a-th and 4a-th ground selection transistors GST3a and GST4a are determined by charges trapped in the data storage pattern DS (e.g., region A) adjacent to the third and fourth ground selection lines GSL3 and GSL4. In this case, because a region where charges are trapped is relatively wide, a charge spreading phenomenon may occur relatively less. In other words, as the 3a-th and 4a-th ground selection transistors GST3a and GST4a are simultaneously programmed, a retention characteristic may be improved.

Alternatively, as the memory device 100 operates, a read disturbance may occur in the ground selection transistors. In this case, the threshold voltages of the ground selection transistors may increase. However, according to implementations of the present disclosure, because at least two adjacent ground selection lines are identically biased, at least two adjacent ground selection transistors connected to the at least two adjacent ground selection lines operate like one cell transistor. In this case, because there is an effect of increasing the cell size, the read disturbance in the ground selection transistors may be prevented or reduced.

Alternatively, as the memory device 100 operates, a potential difference may occur in a cell string channel under a specific bias condition. In this case, hot electron injection (HCI) may occur. This may mean the threshold voltages of cell transistors are increased by the hot electron injection. However, according to implementations of the present disclosure, at least two adjacent ground selection transistors may be simultaneously programmed, and thus, the hot electron injection may be prevented or alleviated.

For example, as illustrated in FIG. 11, at least two adjacent ground selection transistors may be simultaneously programmed to have the a-th program state Pa. In this case, the a-th program state Pa of the at least two adjacent ground selection transistors may be verified by using a verify voltage VVFY.

In implementations, threshold voltages of the at least two adjacent ground selection transistors may be distributed like a b-th program state Pb. In this case, a lower limit value of the b-th program state Pb may be a first level VL1, and the first level VL1 may be lower than the verify voltage VVFY. That is, even though the at least two adjacent ground selection transistors are simultaneously programmed to have the a-th program state Pa, each of the at least two adjacent ground selection transistors may have the b-th program state Pb lower in level than the a-th program state Pa, and thus, a potential difference in a cell string channel under a specific bias condition may be reduced. Accordingly, the hot electron injection may be prevented or alleviated.

As described above, according to implementations of the present disclosure, a plurality of cell strings may be respectively connected to a plurality of string selection lines individually and may share the same ground selection lines. In this case, threshold voltages of a plurality of ground selection transistors may be individually set to control a plurality of cell strings individually, and the GSL coding pattern may be determined such that at least two adjacent ground selection transistors have the same state. The memory device 100 may simultaneously program the at least two adjacent ground selection transistors based on the GSL coding pattern. Accordingly, the change in threshold voltages of ground selection transistors due to various factors may be prevented or minimized. This may mean that the reliability and performance of the memory device 100 are improved.

GSL coding patterns according to various structures of a memory block will be described with reference to the following drawings. For convenience of description, additional description associated with the components described above will be omitted to avoid redundancy.

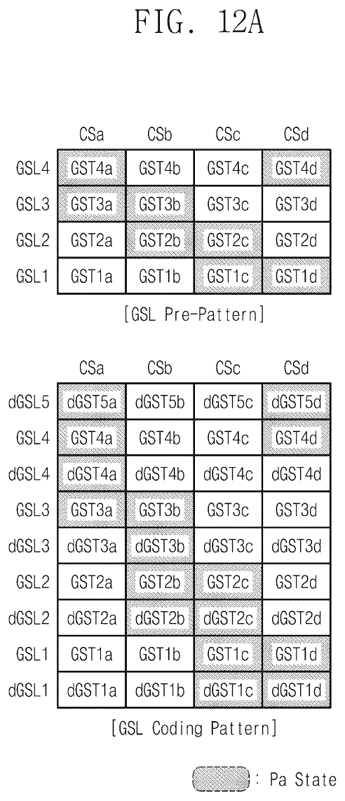

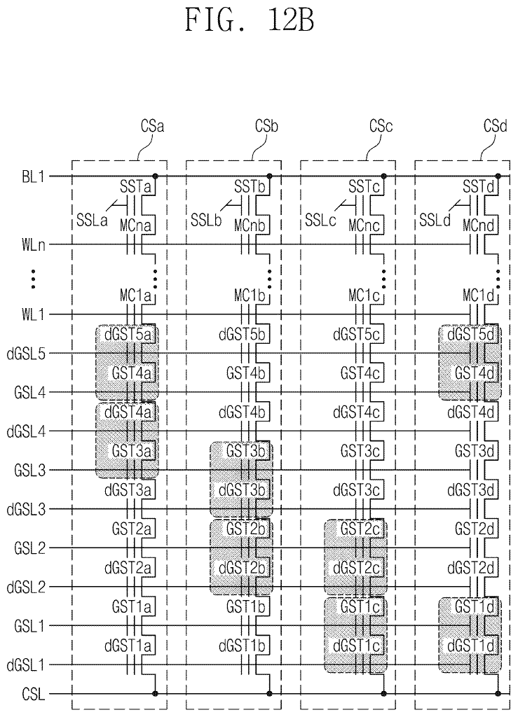

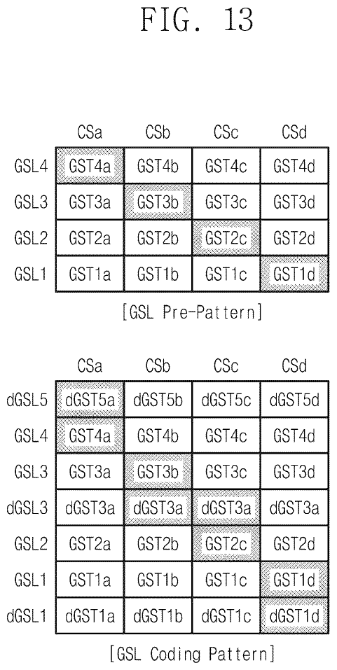

FIGS. 12A and 12B are diagrams for describing a GSL coding pattern according to implementations of the present disclosure. Referring to FIGS. 1, 12A, and 12B, memory blocks included in the memory device 100 may have the 4SSL-1GSL structure. To distinguish four cell strings electrically may be required. In this case, the GSL pre-pattern may be generated as illustrated in FIG. 12A. For example, the GSL pre-patterns may be include patterns of [0011], [0110], [1100], and [1001] for the first to fourth ground selection lines GSL1 to GSL4. The GSL pre-pattern of FIG. 12A is described with reference to FIG. 7, and thus, additional description will be omitted to avoid redundancy.

In implementations, first to fifth dummy ground selection lines dGSL1 to dGSL5 may be provided. The first dummy ground selection line dGSL1 may be provided between the substrate (or the common source line CSL) and the first ground selection line GSL1, the second dummy ground selection line dGSL2 may be provided between the first and second ground selection line lines GSL1 and GSL2, the third dummy ground selection line dGSL3 may be provided between the second and third ground selection line lines GSL2 and GSL3, the fourth dummy ground selection line dGSL4 may be provided between the third and fourth ground selection lines GSL3 and GSL4, and the fifth dummy ground selection line dGSL5 may be provided between the fourth ground selection line GSL4 and the word lines WL1 to WLn.

In this case, the GSL coding pattern may be generated based on the GSL pre-pattern such that at least “i” adjacent ground selection transistors have the same state (i being a multiple of a given number).

For example, the first dummy ground selection line dGSL1 may be set to the same pattern as the first ground selection line GSL1 (i.e., [0011]). In association with the second dummy ground selection line dGSL2, because the 1c-th and 2c-th ground selection transistors GST1c and GST2c of the c-th cell string CSc are programmed to the a-th program state Pa, the second dummy ground selection line dGSL2 may be set to the pattern of [0110]. In association with the third dummy ground selection line dGSL3, because the 2b-th and 3b-th ground selection transistors GST2b and GST3b of the b-th cell string CSb are programmed to the a-th program state Pa, the third dummy ground selection line dGSL3 may be set to the pattern of [0100]. In association with the fourth dummy ground selection line dGSL4, because the 3a-th and 4a-th ground selection transistors GST3a and GST4a of the a-th cell string CSa are programmed to the a-th program state Pa and the number of adjacent ground selection transistors dGST2b, GST2b, dGST3b, and GST3b having the same state in the b-th cell string CSb is “4”, the fourth dummy ground selection line dGSL4 may be set to the pattern of [1000]. The fifth dummy ground selection line dGSL5 may be set to the same pattern as the fourth ground selection line GSL4 (i.e., [1001]).

When the pattern for the dummy ground selection lines dGSL1 to dGSL5 is set as described above, the number of adjacent ground selection transistors having the same state in each cell string may be “i” (i being a multiple of a given number (e.g., a multiple of 2)).

The memory device 100 may perform the multi-GSL program operation based on the generated GSL coding pattern. For example, as illustrated in FIG. 12B, in association with the a-th cell string CSa, the memory device 100 may simultaneously program the 3a-th ground selection transistor GST3a and the 4a-th dummy ground selection transistor dGST4a and may simultaneously program the 4a-th ground selection transistor GST4a and the 5a-th dummy ground selection transistor dGST5a. In association with the b-th cell string CSb, the memory device 100 may simultaneously program the 2b-th dummy ground selection transistor dGST2b and the 2b-th ground selection transistor GST2b and may simultaneously program the 3b-th dummy ground selection transistor dGST3b and the 3b-th ground selection transistor GST3b. In association with the c-th cell string CSc, the memory device 100 may simultaneously program the 1c-th dummy ground selection transistor dGST1c and the 1c-th ground selection transistor GST1c and may simultaneously program the 2c-th dummy ground selection transistor dGST2c and the 2c-th ground selection transistor GST2c. In association with the d-th cell string CSd, the memory device 100 may simultaneously program the 1d-th dummy ground selection transistor dGST1d and the 1d-th ground selection transistor GST1d and may simultaneously program the 4d-th ground selection transistor GST4d and the 5d-th dummy ground selection transistor dGST5d.

In implementations, when the a-th cell string CSa is selected, the second on-voltage VON2 may be applied to the third and fourth ground selection lines GSL3 and GSL4, the second on-voltage VON2 may be applied to the dummy ground selection line lines dGSL1 to dGSL5, and the first on-voltage VON1 may be applied to the first and second ground selection lines GSL1 and GSL2. In this case, all the ground selection transistors of the a-th cell string CSa are turned on, the 2b-th ground selection transistor GST2b of the b-th cell string CSb is turned off, the 1c-th ground selection transistor GST1c of the c-th cell string CSc is turned off, and the 1d-th ground selection transistor GST1d of the d-th cell string CSd is turned off. Accordingly, the remaining cell strings CSb, CSc, and CSd other than the a-th cell string CSa being the selected cell string may be electrically separated from the common source line CSL.

FIG. 13 is a diagram for describing a GSL coding pattern according to implementations of the present disclosure. Referring to FIGS. 1 and 13, memory blocks included in the memory device 100 may have the 4SSL-1GSL structure. To distinguish four cell strings electrically may be required. In this case, the GSL pre-pattern may be generated as illustrated in FIG. 13. For example, the GSL pre-patterns may be include patterns of [0001], [0010], [0100], and for the first to fourth ground selection lines GSL1 to GSL4.

In implementations, the first, third, and fifth dummy ground selection lines dGSL1, dGSL3, and dGSL5 may be provided. The first dummy ground selection line dGSL1 may be provided between the substrate (or the common source line CSL) and the first ground selection line GSL1, the third dummy ground selection line dGSL3 may be provided between the second and third ground selection line lines GSL2 and GSL3, and the fifth dummy ground selection line dGSL5 may be provided between the fourth ground selection line GSL4 and the word lines WL1 to WLn.

In this case, the GSL coding pattern may be generated based on the GSL pre-pattern such that at least “i” adjacent ground selection transistors have the same state (i being a multiple of a given number).

For example, the first dummy ground selection line dGSL1 may be set to the same pattern as the first ground selection line GSL1 (i.e., [0001]). The third dummy ground selection line dGSL3 may be set to [0110], based on patterns of the second and third ground selection line lines GSL2 and GSL3. The fifth dummy ground selection line dGSL5 may be set to the same pattern as the fourth ground selection line GSL4 (i.e., [1000]).

When the pattern for the dummy ground selection lines dGSL1, dGSL3, and dGSL5 is set as described above, the number of adjacent ground selection transistors having the same state in each cell string may be “2”. That is, the GSL coding pattern may be generated such that at least two adjacent ground selection transistors have the same state.

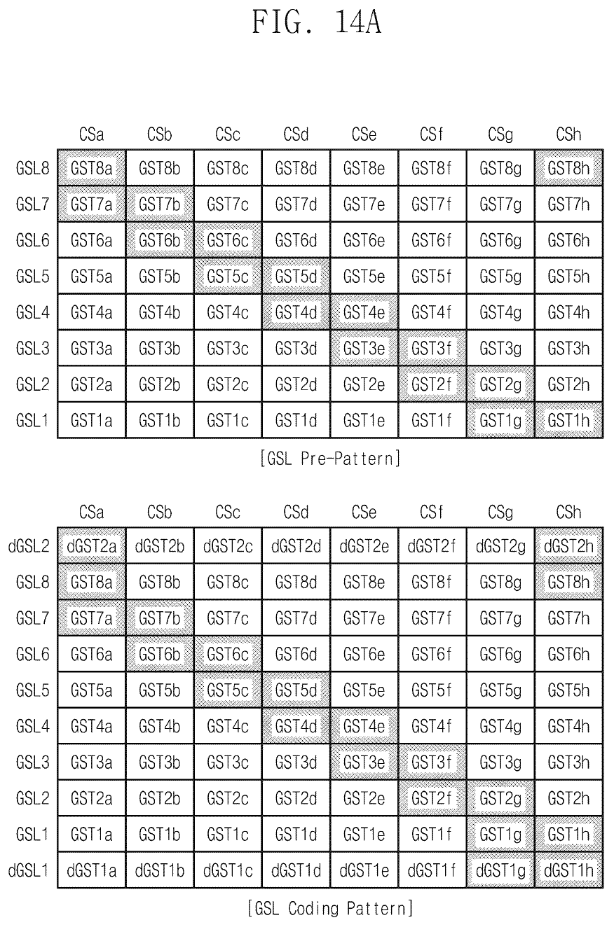

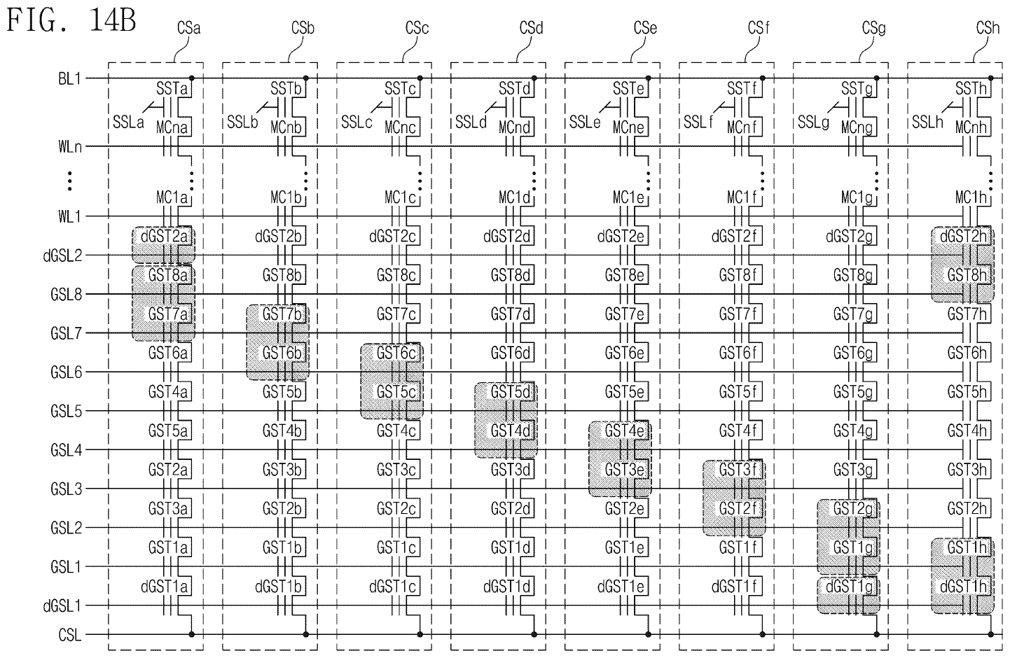

FIGS. 14A and 14B are diagrams for describing a GSL coding pattern according to implementations of the present disclosure. Referring to FIGS. 1, 14A, and 14B, memory blocks included in the memory device 100 may have the 8SSL-1GSL structure. That is, eight cell strings may be respectively connected to eight string selection lines and may have the same ground selection line. In this case, to distinguish eight cell strings electrically may be required. In this case, the GSL pre-pattern may be generated as illustrated in FIG. 14A.

For example, a first ground selection line GSL1 may be set to a pattern of [00000011], a second ground selection line GSL2 may be set to a pattern of [00000110], a third ground selection line GSL3 may be set to a pattern of [00001100], a fourth ground selection line GSL4 may be set to a pattern of [00011000], a fifth ground selection line GSL5 may be set to a pattern of [00110000], a sixth ground selection line GSL6 may be set to a pattern of [01100000], a seventh ground selection line GSL7 may be set to a pattern of [11000000], and an eighth ground selection line GSL8 may be set to a pattern of [10000001].

In implementations, the first and second dummy ground selection lines dGSL1 and dGSL2 may be provided. The first dummy ground selection line dGSL1 may be provided between the substrate (or the common source line CSL) and the first ground selection line GSL1, and the second dummy ground selection line dGSL2 may be provided between the eighth ground selection line GSL8 and the plurality of word lines WL1 to WLn.

In this case, the GSL coding pattern may be generated based on the GSL pre-pattern. For example, the first dummy ground selection line dGSL1 may be set to the same pattern as the first ground selection line GSL1 (i.e., [00000011]). The second dummy ground selection line dGSL2 may be set to the same pattern as the eighth ground selection line GSL8 (i.e., [10000001]).

When the pattern for the dummy ground selection lines dGSL1 and dGSL2 is set as described above, the number of adjacent ground selection transistors having the same state in each cell string may be “at least 2 or more”.

The memory device 100 may perform the multi-GSL program operation based on the GSL coding pattern. For example, as illustrated in FIG. 14B, in association with the a-th cell string CSa, the memory device 100 may simultaneously program 7a-th and 8a-th ground selection transistors GST7a and GST8a and may program a 2a-th dummy ground selection transistor dGST2a. In association with the b-th cell string CSb, the memory device 100 may simultaneously program 6b-th and 7b-th ground selection transistors GST6b and GST7b. In association with the c-th cell string CSc, the memory device 100 may simultaneously program 5c-th and 6c-th ground selection transistors GST5c and GST6c. In association with the d-th cell string CSd, the memory device 100 may simultaneously program 4d-th and 5d-th ground selection transistors GST4d and GST5d. In association with the e-th cell string CSe, the memory device 100 may simultaneously program 3e-th and 4e-th ground selection transistors GST3e and GST4e. In association with the f-th cell string CSf, the memory device 100 may simultaneously program 2f-th and 3f-th ground selection transistors GST2f and GST3f. In association with the g-th cell string CSg, the memory device 100 may simultaneously program 1g-th and 2g-th ground selection transistors GST1g and GST2g and may program a 1g-th dummy ground selection transistor dGST1g. In association with the h-th cell string CSh, the memory device 100 may simultaneously program a 1h-th dummy ground selection transistor dGST1h and a 1h-th ground selection transistor GST1h and may simultaneously program an 8h-th ground selection transistor GST8h and a 2h-th dummy ground selection transistor dGST2h.

As described above, because at least two adjacent ground selection transistors are simultaneously programmed for each of the plurality of cell strings CSa to CSh, the reliability and performance of the memory device 100 may be improved.

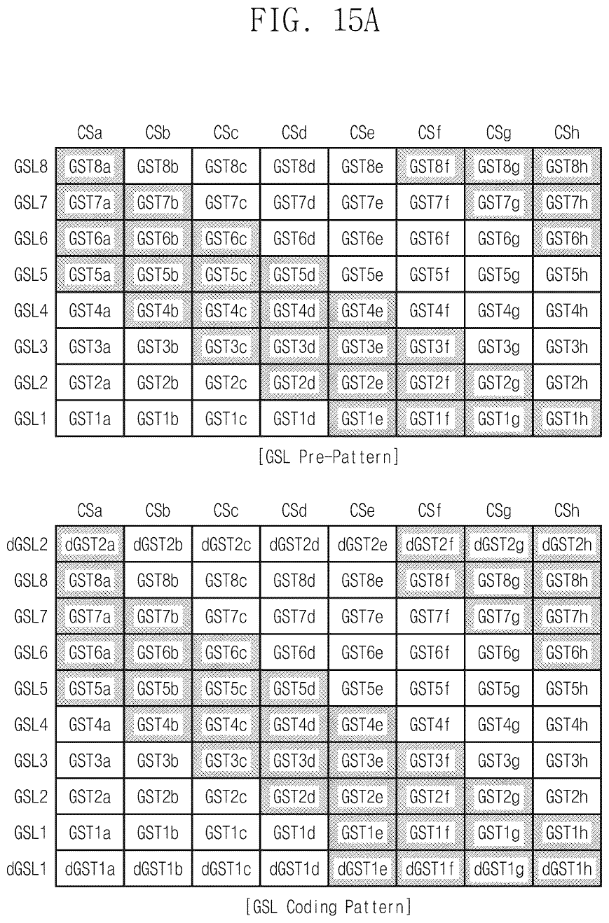

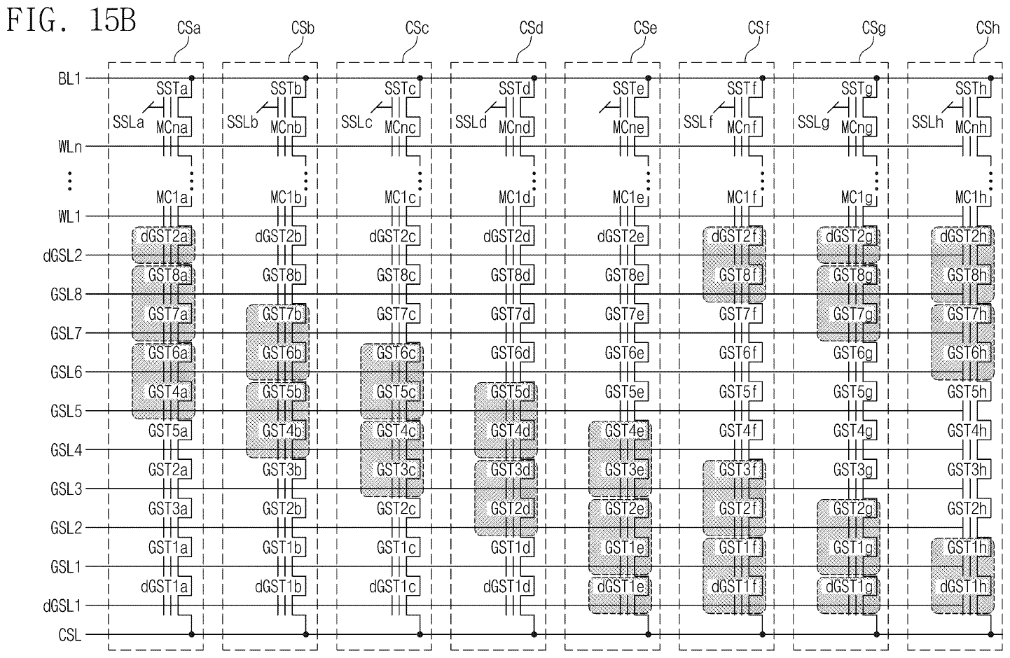

FIGS. 15A and 15B are diagrams for describing a GSL coding pattern according to implementations of the present disclosure. Referring to FIGS. 1, 15A, and 15B, memory blocks included in the memory device 100 may have the 8SSL-1GSL structure. That is, eight cell strings may be respectively connected to eight string selection lines and may have the same ground selection line. In this case, to distinguish eight cell strings electrically may be required. In this case, the GSL pre-pattern may be generated as illustrated in FIG. 15A.

The first ground selection line GSL1 may be set to a pattern of [00001111], the second ground selection line GSL2 may be set to a pattern of [00011110], the third ground selection line GSL3 may be set to a pattern of [00111100], the fourth ground selection line GSL4 may be set to a pattern of [01111000], the fifth ground selection line GSL5 may be set to a pattern of [11110000], the sixth ground selection line GSL6 may be set to a pattern of [11100001], the seventh ground selection line GSL7 may be set to a pattern of [11000011], and the eighth ground selection line GSL8 may be set to a pattern of [10000111].

As the above description, the first dummy ground selection line dGSL1 may be provided between the substrate (or the common source line CSL) and the first ground selection line GSL1, and the second dummy ground selection line dGSL2 may be provided between the eighth ground selection line GSL8 and the plurality of word lines WL1 to WLn.

In this case, the GSL coding pattern may be generated based on the GSL pre-pattern. For example, the first dummy ground selection line dGSL1 may be set to the same pattern as the first ground selection line GSL1 (i.e., [00001111]). The second dummy ground selection line dGSL2 may be set to the same pattern as the eighth ground selection line GSL8 (i.e., [10000111]).

When the pattern for the dummy ground selection lines dGSL1 and dGSL2 is set as described above, the number of adjacent ground selection transistors having the same state in each cell string may be “at least 2 or more”.

The memory device 100 may perform the multi-GSL program operation based on the GSL coding pattern. For example, as illustrated in FIG. 15B, in association with the a-th cell string CSa, the memory device 100 may simultaneously program the 5a-th and 6a-th ground selection transistors GST5a and GST6a, may simultaneously program the 7a-th and 8a-th ground selection transistors GST7a and GST8a, and may program the 2a-th dummy ground selection transistor dGST2a. In association with the b-th cell string CSb, the memory device 100 may simultaneously program the 4b-th and 5b-th ground selection transistors GST4b and GST5b and may simultaneously program the 6b-th and 7b-th ground selection transistors GST6b and GST7b. In association with the c-th cell string CSc, the memory device 100 may simultaneously program the 3c-th and 4c-th ground selection transistors GST3c and GST4c and may simultaneously program the 5c-th and 6c-th ground selection transistors GST5c and GST6c. In association with the d-th cell string CSd, the memory device 100 may simultaneously program the 2d-th and 3d-th ground selection transistors GST2d and GST3d and may simultaneously program the 4d-th and 5d-th ground selection transistors GST4d and GST5d. In association with the e-th cell string CSe, the memory device 100 may simultaneously program the 1e-th and 2e-th ground selection transistors GST1e and GST2e, may simultaneously program the 3e-th and 4e-th ground selection transistors GST3e and GST4e, and may program the 1e-th dummy ground selection transistor dGST1e. In association with the f-th cell string CSf, the memory device 100 may simultaneously program the 1f-th dummy ground selection transistor dGST1f and the 1f-th ground selection transistors GST1f and may simultaneously program the 2f-th and 3f-th ground selection transistors GST2f and GST3f. In some implementations, the memory device 100 can also simultaneously program the 8f-th ground selection transistor GST8f and the 2f-th dummy ground selection transistor dGST2f. In association with the g-th cell string CSg, the memory device 100 may simultaneously program the 1g-th and 2g-th ground selection transistors GST1g and GST2g, may simultaneously program the 7g-th and 8g-th ground selection transistors GST7g and GST8g, may program the 1g-th ground selection transistor dGST1g, and may program the 2g-th dummy ground selection transistor dGST2g. In association with the h-th cell string CSh, the memory device 100 may simultaneously program the 1h-th dummy ground selection transistor dGST1h and the 1h-th ground selection transistor GST1h, may simultaneously program the 6h-th and 7-th ground selection transistors GST6h and GST7h, and may simultaneously program the 8h-th ground selection transistor GST8h and the 2h-th dummy ground selection transistor dGST2h.

As described above, because at least two adjacent ground selection transistors are simultaneously programmed for each of the plurality of cell strings CSa to CSh, the reliability and performance of the memory device 100 may be improved.

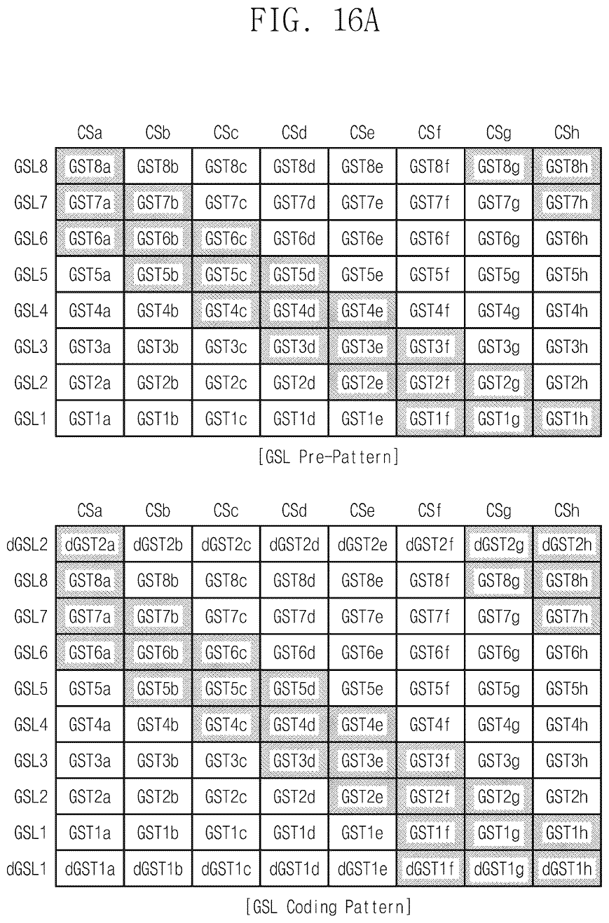

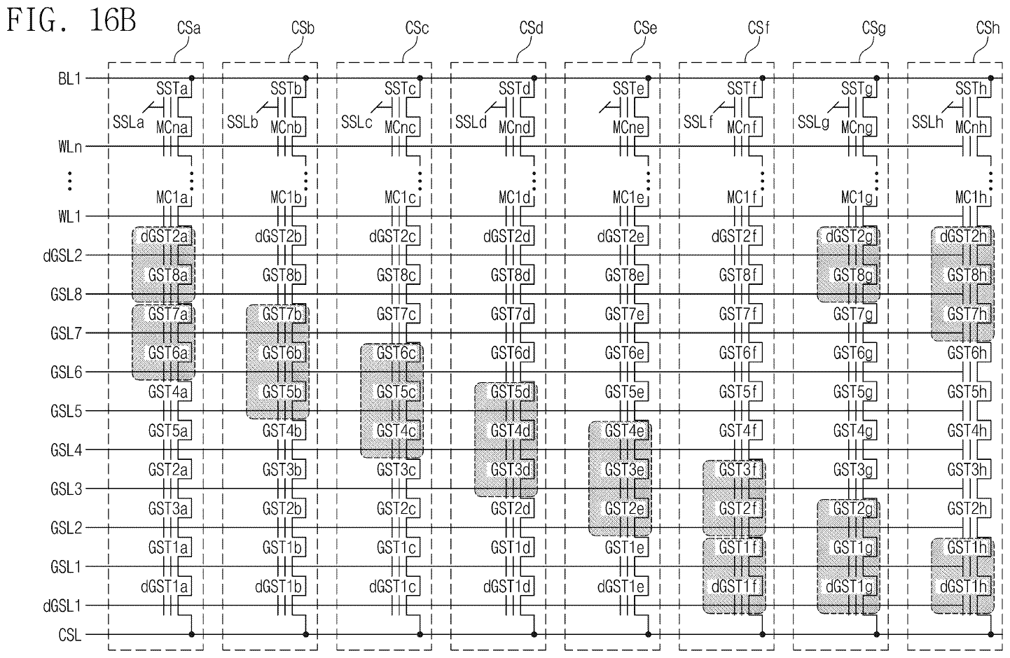

FIGS. 16A and 16B are diagrams for describing a GSL coding pattern according to implementations of the present disclosure. Referring to FIGS. 1, 16A, and 16B, memory blocks included in the memory device 100 may have the 8SSL-1GSL structure. That is, eight cell strings may be respectively connected to eight string selection lines and may have the same ground selection line. In this case, to distinguish eight cell strings electrically may be required. In this case, the GSL pre-pattern may be generated as illustrated in FIG. 16A.

In the above implementations, the GSL pre-pattern is generated based on a multiple of 2. That is, like [00000011], [00001111], etc., in a pattern corresponding to one ground selection line, the GSL pre-pattern is generated such that two or four ground selection transistors have the a-th program state. However, the present disclosure is not limited thereto, and the GSL pre-pattern may be generated based on a natural number of 2 or more.

For example, as illustrated in FIG. 16A, the GSL pre-pattern may be generated based on “3”. For example, the first ground selection line GSL1 may be set to a pattern of [00000111], the second ground selection line GSL2 may be set to a pattern of [000001110], the third ground selection line GSL3 may be set to a pattern of [00011100], the fourth ground selection line GSL4 may be set to a pattern of [00111000], the fifth ground selection line GSL5 may be set to a pattern of [01110000], the sixth ground selection line GSL6 may be set to a pattern of [11100000], the seventh ground selection line GSL7 may be set to a pattern of [11000001], and the eighth ground selection line GSL8 may be set to a pattern of [10000011].

As the above description, the first dummy ground selection line dGSL1 may be provided between the substrate (or the common source line CSL) and the first ground selection line GSL1, and the second dummy ground selection line dGSL2 may be provided between the eighth ground selection line GSL8 and the plurality of word lines WL1 to WLn.

In this case, the GSL coding pattern may be generated based on the GSL pre-pattern. For example, the first dummy ground selection line dGSL1 may be set to the same pattern as the first ground selection line GSL1 (i.e., [00000111]). The second dummy ground selection line dGSL2 may be set to the same pattern as the eighth ground selection line GSL8 (i.e., [10000011]).

When the pattern for the dummy ground selection lines dGSL1 and dGSL2 is set as described above, the number of adjacent ground selection transistors having the same state in each cell string may be “at least 2 or more”.

The memory device 100 may perform the multi-GSL program operation based on the GSL coding pattern. In the above implementations, the memory device 100 may simultaneously program two adjacent ground selection transistors, but the present disclosure is not limited thereto. For example, the memory device 100 may simultaneously program “n” adjacent ground selection transistors (n being a natural number of 2 or more).

For example, as illustrated in FIG. 16B, in association with the a-th cell string CSa, the memory device 100 may simultaneously program the 6a-th and 7a-th ground selection transistors GST6a and GST7a and may simultaneously program the 8a-th ground selection transistors GST8a and the 2a-th dummy ground selection transistor dGST2a. In association with the b-th cell string CSb, the memory device 100 may simultaneously program the 5b-th, 6b-th, and 7b-th ground selection transistors GST5b, GST6b, and GST7b. In association with the c-th cell string CSc, the memory device 100 may simultaneously program the 4c-th, 5c-th, and 6c-th ground selection transistors GST4c, GST5c, and GST6c. In association with the d-th cell string CSd, the memory device 100 may simultaneously program the 3d-th, 4d-th, and 5d-th ground selection transistors GST3d, GST4d, and GST5d. In association with the e-th cell string CSe, the memory device 100 may simultaneously program the 2e-th, 3e-th, and 4e-th ground selection transistors GST2e, GST3e, and GST4e. In association with the f-th cell string CSf, the memory device 100 may simultaneously program the 1f-th dummy ground selection transistor dGST1f and the 1f-th ground selection transistors GST1f and may simultaneously program the 2f-th and 3f-th ground selection transistors GST2f and GST3f. In association with the g-th cell string CSg, the memory device 100 may simultaneously program the 1g-th dummy ground selection transistor dGST1g and the 1g-th and 2g-th ground selection transistor GST1g and GST2g and may simultaneously program the 8g-th ground selection transistor GST8g and the 2g-th dummy ground selection transistor dGST2g. In association with the h-th cell string CSh, the memory device 100 may simultaneously program the 1h-th dummy ground selection transistor dGST1h and the 1h-th ground selection transistor GST1h and may simultaneously program the 7h-th and 8h-th ground selection transistors GST7h and GST8h and the 2h-th dummy ground selection transistor dGST2h.

As described above, the memory device 100 may perform the multi-GSL program operation based on the GSL coding pattern such that at least two adjacent ground selection transistors are simultaneously programmed. In this case, the number of adjacent ground selection transistors to be simultaneously programmed may be a natural number of 2 or more. In the above implementations, when adjacent ground selection transistors having the same state include a dummy ground selection transistor and the number of adjacent ground selection transistors is a multiple of a given number, the dummy ground selection transistor may be individually programmed. However, the present disclosure is not limited thereto. For example, the number of adjacent ground selection transistors to be simultaneously programmed may be variously changed or modified such that the dummy ground selection transistor is simultaneously programmed together with any other ground selection transistor. For example, as illustrated in FIG. 15B, the 5a-th, 6a-th, 7a-th, and 8a-th ground selection transistors GST5a, GST6a, GST7a, and GST8a and the 2a-th dummy ground selection transistor dGST2a of the a-th cell string CSa may be programmed to the a-th program state Pa. In this case, the memory device 100 may simultaneously program the 5a-th and 6a-th ground selection transistors GST5a and GST6a, may simultaneously program the 7a-th and 8a-th ground selection transistors GST7a and GST8a and the 2a dummy ground selection transistor dGST2a. That is, at a dummy ground selection line, when the number of ground selection transistors to be programmed is 5, the memory device 100 may simultaneously program two ground selection transistors and may simultaneously program the remaining three ground selection transistors.

The above order of the multi-GSL program operations and the number of ground selection transistors to be simultaneously programmed may be variously changed and modified, and the present disclosure is not limited thereto.

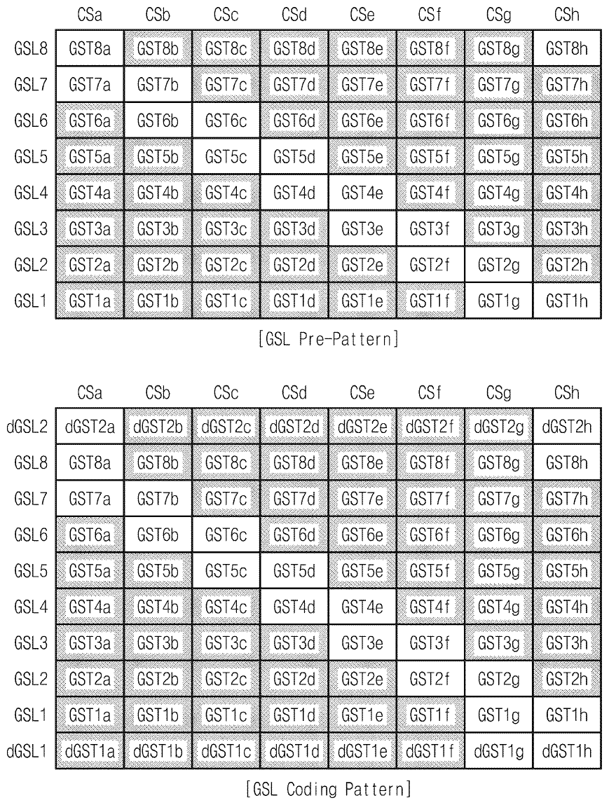

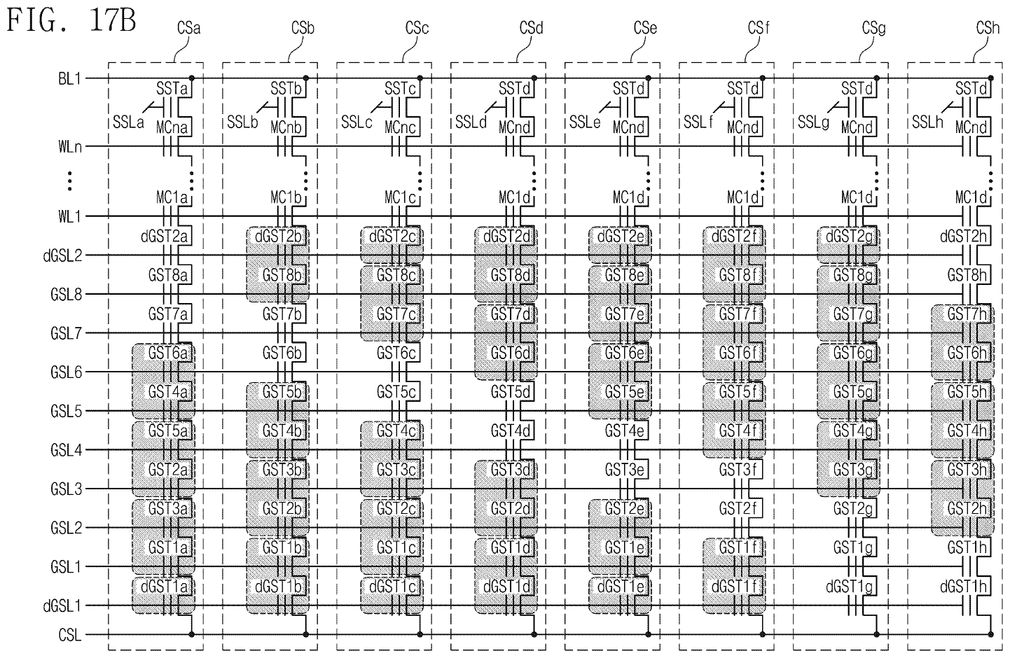

FIGS. 17A and 17B are diagrams for describing a GSL coding pattern according to implementations of the present disclosure. Referring to FIGS. 1, 17A, and 17B, memory blocks included in the memory device 100 may have the 8SSL-1GSL structure. That is, eight cell strings may be respectively connected to eight string selection lines and may have the same ground selection line. In this case, to distinguish eight cell strings electrically may be required. In this case, the GSL pre-pattern may be generated as illustrated in FIG. 17A.

For example, the first ground selection line GSL1 may be set to a pattern of [11111100], the second ground selection line GSL2 may be set to a pattern of [11111001], the third ground selection line GSL3 may be set to a pattern of [11110011], the fourth ground selection line GSLA may be set to a pattern of [11100111], the fifth ground selection line GSL5 may be set to a pattern of [11001111], the sixth ground selection line GSL6 may be set to a pattern of [10011111], the seventh ground selection line GSL7 may be set to a pattern of [00111111], and the eighth ground selection line GSL8 may be set to a pattern of [01111110].

In implementations, the first and second dummy ground selection lines dGSL1 and dGSL2 may be provided. The first dummy ground selection line dGSL1 may be provided between the substrate (or the common source line CSL) and the first ground selection line GSL1, and the second dummy ground selection line dGSL2 may be provided between the eighth ground selection line GSL8 and the plurality of word lines WL1 to WLn.

In this case, the GSL coding pattern may be generated based on the GSL pre-pattern. For example, the first dummy ground selection line dGSL1 may be set to the same pattern as the first ground selection line GSL1 (i.e., [11111100]). The second dummy ground selection line dGSL2 may be set to the same pattern as the eighth ground selection line GSL8 (i.e., [01111110]).

The memory device 100 may perform the multi-GSL program operation based on the GSL coding pattern. For example, as illustrated in FIG. 17B, the memory device 100 may simultaneously program at least two adjacent ground selection transistors based on the GSL coding pattern. The multi-GSL program operation for ground selection transistors of the memory device 100 illustrated in FIG. 17B is similar to the method described above, and thus, additional description will be omitted to avoid redundancy.

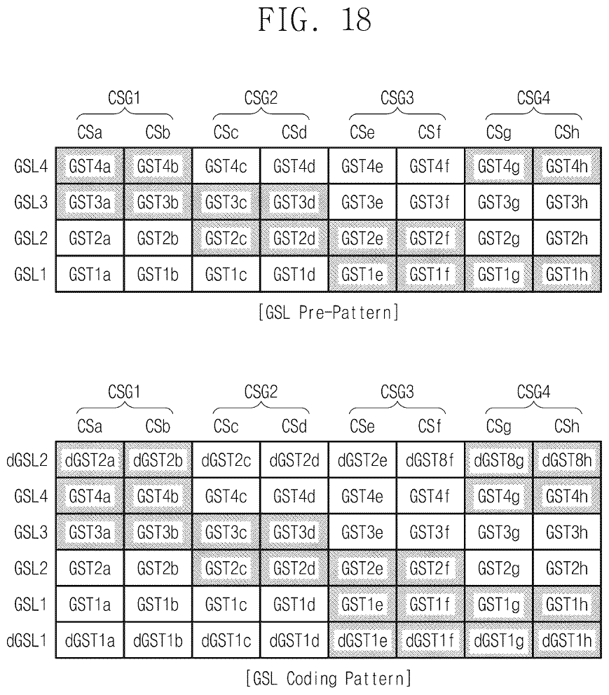

FIG. 18 is a diagram for describing a GSL coding pattern according to implementations of the present disclosure. Referring to FIGS. 1 and 18, memory blocks included in the memory device 100 may have the 8SSL-1GSL structure. That is, eight cell strings may be respectively connected to eight string selection lines and may have the same ground selection line. In this case, to distinguish four cell string groups electrically may be required. In this case, the GSL pre-pattern may be generated as illustrated in FIG. 18.

For example, the number of cell strings to be electrically separated (or the number of cell string groups) may be 4. In this case, the GSL pre-pattern for four ground selection lines GSL1 to GSL4 may be generated. The first ground selection line GSL1 may be set to a pattern of [00001111], the second ground selection line GSL2 may be set to a pattern of [00111100], the third ground selection line GSL3 may be set to a pattern of [11110000], and the fourth ground selection line GSL4 may be set to a pattern of [11000011].

As the above description, the first dummy ground selection line dGSL1 may be provided between the substrate (or the common source line CSL) and the first ground selection line GSL1, and the second dummy ground selection line dGSL2 may be provided between the fourth ground selection line GSL4 and the plurality of word lines WL1 to WLn.

In this case, the GSL coding pattern may be generated based on the GSL pre-pattern. For example, the first dummy ground selection line dGSL1 may be set to the same pattern as the first ground selection line GSL1 (i.e., [00001111]). The second dummy ground selection line dGSL2 may be set to the same pattern as the eighth ground selection line GSL8 (i.e., [11000011]).

When the pattern for the dummy ground selection lines dGSL1 and dGSL2 is set as described above, the number of adjacent ground selection transistors having the same state in each cell string may be “at least 2 or more”. The memory device 100 may perform the multi-GSL program operation based on the GSL coding pattern.

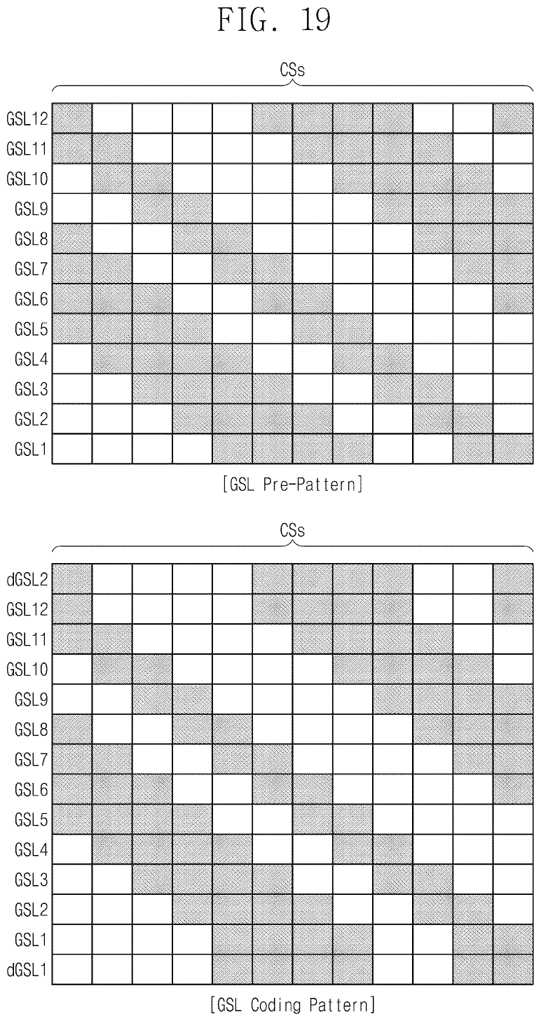

FIG. 19 is a diagram for describing a GSL coding pattern according to implementations of the present disclosure. Referring to FIGS. 1 and 19, memory blocks included in the memory device 100 may have the 12SSL-1GSL structure. That is, 12 cell strings may be connected to twelve string selection lines and may have the same ground selection line. In this case, to separate 12 cell strings electrically may be required. In this case, as illustrated in FIG. 19, the GSL pre-pattern for 12 ground selection lines GSL1 to GSL12 may be generated.

For example, a first ground selection line GSL1 may be set to a pattern of [000011110011], a second ground selection line GSL2 may be set to a pattern of [000111100110], a third ground selection line GSL3 may be set to a pattern of [001111001100], a fourth ground selection line GSL4 may be set to a pattern of [011110011000], a fifth ground selection line GSL5 may be set to a pattern of [111100110000], a sixth ground selection line GSL6 may be set to a pattern of [111001100001], a seventh ground selection line GSL7 may be set to a pattern of [110011000011], an eighth ground selection line GSL8 may be set to a pattern of [100110000111], a ninth ground selection line GSL9 may be set to a pattern of [001100001111], a tenth ground selection line GSL10 may be set to a pattern of [011000011110], an eleventh ground selection line GSL11 may be set to a pattern of [110000111100], and a twelfth ground selection line GSL12 may be set to a pattern of [100001111001].

As the above description, the first dummy ground selection line dGSL1 may be provided between the substrate (or the common source line CSL) and the first ground selection line GSL1, and the second dummy ground selection line dGSL2 may be provided between the twelfth ground selection line GSL12 and the plurality of word lines WL1 to WLn.

In this case, the GSL coding pattern may be generated based on the GSL pre-pattern. For example, the first dummy ground selection line dGSL1 may be set to the same pattern as the first ground selection line GSL1 (i.e., [000011110011]). The second dummy ground selection line dGSL2 may be set to the same pattern as the twelfth ground selection line GSL12 (i.e., [100001111001]).

When the pattern for the dummy ground selection lines dGSL1 and dGSL2 is set as described above, the number of adjacent ground selection transistors having the same state in each cell string may be “at least 2 or more”.

The memory device 100 may perform the multi-GSL program operation based on the GSL coding pattern. The multi-GSL program operation based on the GSL coding pattern is described above, and thus, additional description will be omitted to avoid redundancy.

The implementations of FIG. 19 is only an example, and the present disclosure is not limited thereto. For example, the GSL pre-pattern for 12 ground selection lines GSL1 to GSL12 may be generated based on at least one of the methods described with reference to FIGS. 1 to 18.

The GSL coding pattern described in the above implementations are only examples, and the present disclosure is not limited thereto. For example, the GSL coding-pattern may be generated such that at least two adjacent ground selection transistors have the same state. In the GSL coding pattern described in the above implementations, the inversion for the a-th program state Pa and the erase state “E” may also be possible.

Implementations of the present disclosure are above described based on a plurality of cell strings connected to one bit line (e.g., BL1). However, the present disclosure is not limited thereto. The above implementations may be applicable to cell strings respectively connected to a plurality of bit lines. For example, ground selection transistors of the 1a-th cell string CS1a connected to the first bit line BL1 and the a-th string selection line SSLa and ground selection transistors of the 2a-th cell string CS2a connected to the second bit line BL2 and the a-th string selection line SSLa may be programmed to the same pattern or the same state.

The above implementations of the present disclosure are provided to describe the present disclosure easily, and the present disclosure is not limited thereto. For example, according to implementations of the present disclosure, a plurality of cell strings may be respectively connected to a plurality of string selection lines and may share the same ground selection line. In this case, in each of the plurality of cell strings, at least two ground selection transistors may have the same state (e.g., the erase state “E” or the a-th program state Pa). As an example, at least two ground selection transistors may be simultaneously programmed. Accordingly, the change in a threshold voltage of a ground selection transistor caused by various factors may be prevented or minimized. This may mean that the reliability and performance of the memory device 100 are improved.

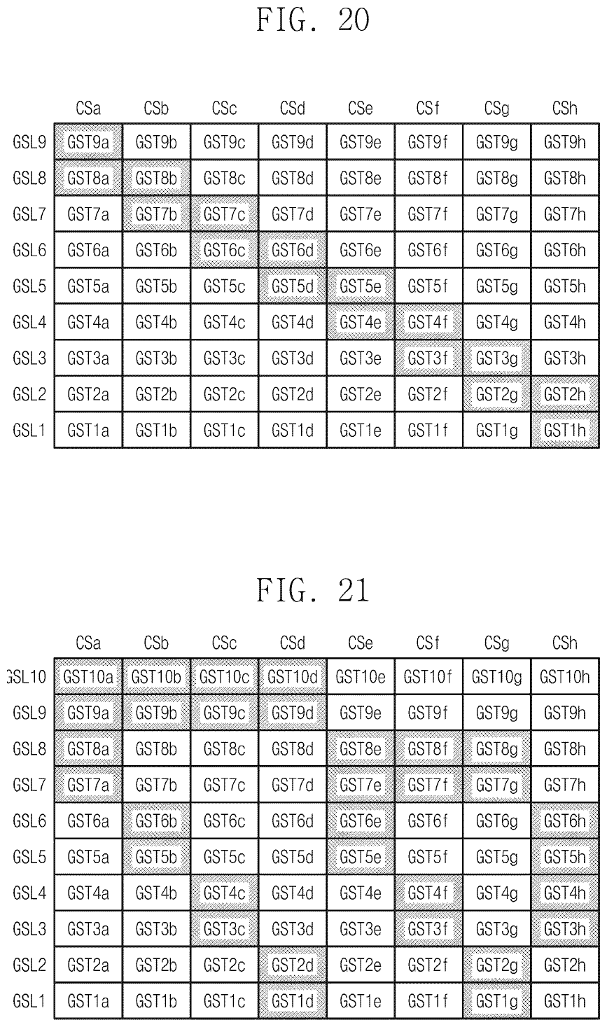

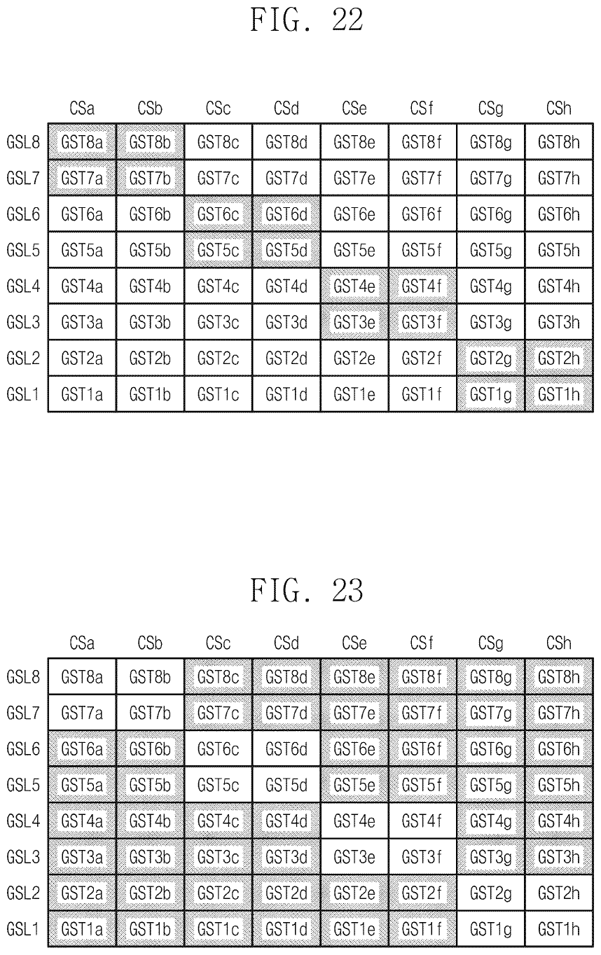

FIGS. 20 and 21 are diagrams for describing a GSL coding pattern according to implementations of the present disclosure. Referring to FIGS. 1, 20, and 21, memory blocks included in the memory device 100 may have the 8SSL-1GSL of structure. That is, 8 cell strings may be connected to eight string selection lines and may have the same ground selection line. In this case, to distinguish eight cell strings electrically may be required, and the GSL coding pattern may be generated as illustrated in FIG. 21 or 22. For example, in the above implementations, the GSL pre-pattern may be generated based on the structure of a memory block, and the GSL coding pattern may be generated based the GSL pre-pattern such that dummy ground selection lines have the same pattern as adjacent ground selection lines. In contrast, in the implementations of FIG. 21, a dummy ground selection line may not be required.

For example, as illustrated in FIG. 21, a first ground selection line GSL1 may be set to a pattern of [00000001], a second ground selection line GSL2 may be set to a pattern of [00000011], a third ground selection line GSL3 may be set to a pattern of [00000110], a fourth ground selection line GSL4 may be set to a pattern of [00001100], a fifth ground selection line GSL5 may be set to a pattern of [00011000], a sixth ground selection line GSL6 may be set to a pattern of [00110000], a seventh ground selection line GSL7 may be set to a pattern of [01100000], an eighth ground selection line GSL8 may be set to a pattern of [11000000], and a ninth ground selection line GSL9 may be set to a pattern of [10000000].

In this case, at least two adjacent ground selection transistors may have the same program state, and one of the cell strings CSa to CSh may be selected depending on-voltages of the plurality of ground selection lines GSL1 to GSL9.

Alternatively, as illustrated in FIG. 21, a first ground selection line GSL1 may be set to a pattern of [00010010], a second ground selection line GSL2 may be set to a pattern of [00010010], a third ground selection line GSL3 may be set to a pattern of [00100101], a fourth ground selection line GSL4 may be set to a pattern of [00100101], a fifth ground selection line GSL5 may be set to a pattern of [01001001], a sixth ground selection line GSL6 may be set to a pattern of [01001001], a seventh ground selection line GSL7 may be set to a pattern of [10001110], an eighth ground selection line GSL8 may be set to a pattern of [10001110], a ninth ground selection line GSL9 may be set to a pattern of [11110000], and a tenth ground selection line GSL10 may be set to a pattern of [11110000].

In this case, at least two adjacent ground selection transistors may have the same program state, and one of the cell strings CSa to CSh may be selected depending on-voltages of the plurality of ground selection lines GSL1 to GSL10.

FIGS. 22 and 23 are diagrams for describing a GSL coding pattern according to some implementations of the present disclosure. Referring to FIGS. 1, 22, and 23, memory blocks included in the memory device 100 may have a structure of 8SSL-1GSL. That is, 8 cell strings may be connected to eight string selection lines and may be the same ground selection line.

In implementations, it is required to distinguish four cell string groups. In this case, as illustrated in FIG. 22, ground selection transistors GST1a to GST1h connected to the first ground selection line GSL1 may be programmed to have a pattern of [00000011], ground selection transistors GST2a to GST2h connected to the second ground selection line GSL2 may be programmed to have a pattern of [00000011], ground selection transistors GST3a to GST3h connected to the third ground selection line GSL3 may be programmed to have a pattern of [00001100], ground selection transistors GST4a to GST4h connected to the fourth ground selection line GSL4 may be programmed to have a pattern of [00001100], ground selection transistors GST5a to GST5h connected to the fifth ground selection line GSL5 may be programmed to have a pattern of [00110000], ground selection transistors GST6a to GST6h connected to the sixth ground selection line GSL6 may be programmed to have a pattern of [00110000], ground selection transistors GST7a to GST7h connected to the seventh ground selection line GSL7 may be programmed to have a pattern of [11000000], and ground selection transistors GST8a to GST8h connected to the eighth ground selection line GSL8 may be programmed to have a pattern of [11000000].

Alternatively, as illustrated in FIG. 23, the first ground selection line GSL1 may be programmed to have a pattern of [11111100], ground selection transistors GST2a to GST2h connected to the second ground selection line GSL2 may be programmed to have a pattern of [11111100], ground selection transistors GST3a to GST3h connected to the third ground selection line GSL3 may be programmed to have a pattern of [11110011], ground selection transistors GST4a to GST4h connected to the fourth ground selection line GSL4 may be programmed to have a pattern of [11110011], ground selection transistors GST5a to GST5h connected to the fifth ground selection line GSL5 may be programmed to have a pattern of [11001111], ground selection transistors GST6a to GST6h connected to the sixth ground selection line GSL6 may be programmed to have a pattern of [11001111], ground selection transistors GST7a to GST7h connected to the seventh ground selection line GSL7 may be programmed to have a pattern of [00111111], and ground selection transistors GST8a to GST8h connected to the eighth ground selection line GSL8 may be programmed to have a pattern of [00111111].

In implementations in FIGS. 22 and 23, at least two adjacent ground selection transistors in each of the plurality of cell strings CSa to CSh may have the same program state or the same threshold state.

In implementations in FIGS. 22 and 23, an implementation in which two cell strings are controlled together is described, but the scope of the present disclosure is not limited thereto. For example, each of the plurality of cell strings CSa to CSh may be individually controlled. Here, at least two adjacent ground selection transistors in each of the plurality of cell strings CSa to CSh may have the same program state or the same threshold state. In this case, the first ground selection line GSL1 may be programmed to have a pattern of [00000001], ground selection transistors GST2a to GST2h connected to the second ground selection line GSL2 may be programmed to have a pattern of [00000001], ground selection transistors GST3a to GST3h connected to the third ground selection line GSL3 may be programmed to have a pattern of [00000010], ground selection transistors GST4a to GST4h connected to the fourth ground selection line GSL4 may be programmed to have a pattern of [00000010]. Other ground transistors may have a similar pattern as above described, and thus additional description will be omitted to avoid redundancy.

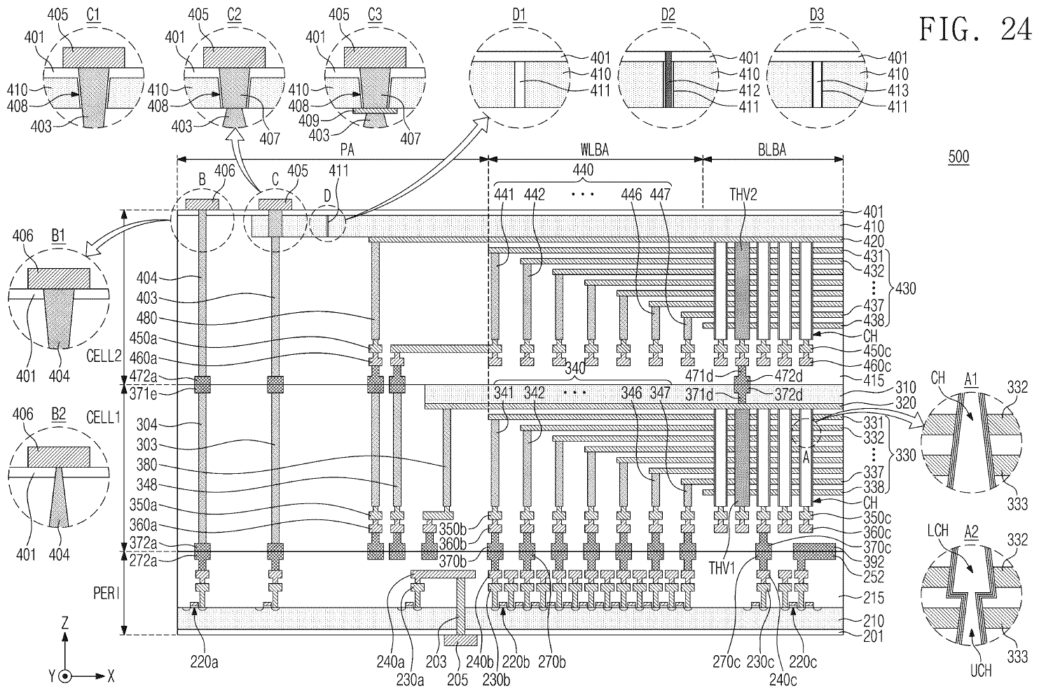

FIG. 24 illustrates a view for describing a memory device according to implementations of the present disclosure.

Referring to FIG. 24, the memory device 500 may have a chip-to-chip (C2C) structure. Herein, in the C2C structure, after fabricating at least one upper chip including a cell region and at least one lower chip including a peripheral circuit region PERI, respectively, the upper chip and the lower chip may be bonded to each other by a bonding method. As an example, the bonding method may mean a method of electrically or physically connecting a bonding metal pattern formed in the uppermost metal layer of the upper chip and a bonding metal pattern formed in the uppermost metal layer of the lower chip. For example, when the bonding metal patterns are formed of copper (Cu), the bonding method may be referred to as a “Cu—Cu bonding method”. As another example, the bonding metal patterns may also be formed of aluminum (Al) or tungsten (W).

The memory device 500 may include at least one upper chip including a cell region. For example, as illustrated in FIG. 24, the memory device 500 may be implemented to include two upper chips. However, this is illustrative, and the number of upper chips is not limited thereto. In the case in which the memory device 500 is implemented to include two upper chips, the memory device 500 may be manufactured by separately manufacturing a first upper chip including a first cell region CELL1, a second upper chip including a second cell region CELL2, and a lower chip including a peripheral circuit region PERI and thereafter connecting the first upper chip, the second upper chip, and the lower chip by a bonding method. The first upper chip may be turned over and connected to the lower chip by the bonding method, and the second upper chip may also be turned over and connected to the first upper chip by the bonding method. In the following description, upper portions and lower portions of the first and second upper chips are defined based on before the first upper chip and the second upper chip are turned over. That is, in FIG. 24, an upper portion of the lower chip refers to an upper portion defined based on a +Z-axis direction, and the upper portions of the first and second upper chips refer to upper portions defined based on a −Z-axis direction. However, this is illustrative, and only one of the first upper chip and the second upper chip may be turned over and connected by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b, and 220c formed on the first substrate 210. An interlayer insulating layer 215 including one or more insulating layers may be provided on the plurality of circuit elements 220a, 220b, and 220c, and a plurality of metal lines connecting the plurality of circuit elements 220a, 220b, and 220c may be provided in the interlayer insulating layer 215. For example, the plurality of metal lines may include first metal lines 230a, 230b, and 230c connected with the plurality of circuit elements 220a, 220b, and 220c, respectively, and second metal lines 240a, 240b, and 240c formed on the first metal lines 230a, 230b, and 230c. The plurality of metal lines may be formed of at least one of various conductive materials. For example, the first metal lines 230a, 230b, and 230c may be formed of tungsten having a relatively high electrical resistivity, and the second metal lines 240a, 240b, and 240c may be formed of copper having a relatively low electrical resistivity.

In this specification, only the first metal lines 230a, 230b, and 230c and the second metal lines 240a, 240b, and 240c are illustrated and described. However, without being limited thereto, one or more additional metal lines may be further formed on the second metal lines 240a, 240b, and 240c. In this case, the second metal lines 240a, 240b, and 240c may be formed of aluminum At least some of the additional metal lines formed on the second metal lines 240a, 240b, and 240c may be formed of copper having a lower electrical resistivity than the aluminum of the second metal lines 240a, 240b, and 240c.

The interlayer insulating layer 115 may be disposed on the first substrate 210 and may include an insulating material, such as silicon oxide or silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (the Z-axis direction) perpendicular to an upper surface of the second substrate 310. String selection lines and a ground selection line may be disposed on and under the word lines 330, and the plurality of word lines 330 may be disposed between the string selection lines and the ground selection line. Likewise, the second cell region CELL2 may include a third substrate 410 and a common source line 420, and a plurality of word lines 430 (431 to 438) may be stacked in a direction (the Z-axis direction) perpendicular to an upper surface of the third substrate 410. The second substrate 310 and the third substrate 410 may be formed of various materials and may be, for example, silicon substrates, silicon-germanium substrates, germanium substrates, or substrates having mono-crystalline epitaxial layers grown on mono-crystalline silicon substrates. A plurality of channel structures CH may be formed in the first and second cell regions CELL1 and CELL2.

In implementations, as illustrated in A1, the channel structure CH may be provided in the bit line bonding region BLBA and may extend in the direction perpendicular to the upper surface of the second substrate 310 to penetrate the word lines 330, the string selection lines, and the ground selection line. The channel structure CH may include a data storage layer, a channel layer, and a buried insulating layer. The channel layer may be electrically connected with a first metal line 350c and a second metal line 360c in the bit line bonding region BLBA. For example, the second metal line 360c may be a bit line and may be connected to the channel structure CH through the first metal line 350c. The bit line 360c may extend in a first direction (a Y-axis direction) parallel to the upper surface of the second substrate 310.

In implementations, as illustrated in A2, the channel structure CH may include a lower channel LCH and an upper channel UCH connected to each other. For example, the channel structure CH may be formed through a process for the lower channel LCH and a process for the upper channel UCH. The lower channel LCH may extend in the direction perpendicular to the upper surface of the second substrate 310 and may penetrate the common source line 320 and the lower word lines 331 and 332. The lower channel LCH may include a data storage layer, a channel layer, and a buried insulating layer and may be connected with the upper channel UCH. The upper channel UCH may penetrate the upper word lines 333 to 338. The upper channel UCH may include a data storage layer, a channel layer, and a buried insulating layer, and the channel layer of the upper channel UCH may be electrically connected with the first metal line 350c and the second metal line 360c. As the length of a channel is increased, it may be difficult to form a channel having a constant width due to process reasons. The memory device 500 according to implementations of the present disclosure may include a channel having improved width uniformity through the lower channel LCH and the upper channel UCH formed by sequential processes.

In the case in which the channel structure CH includes the lower channel LCH and the upper channel UCH as illustrated in A2, a word line located near the boundary between the lower channel LCH and the upper channel UCH may be a dummy word line. For example, the word line 332 and the word line 333 that form the boundary between the lower channel LCH and the upper channel UCH may be dummy word lines. In this case, data may not be stored in memory cells connected to the dummy word lines. Alternatively, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

Meanwhile, it is illustrated in A2 that the number of lower word lines 331 and 332 penetrated by the lower channel LCH is smaller than the number of upper word lines 333 to 338 penetrated by the upper channel UCH. However, this is illustrative, and the present disclosure is not limited thereto. In another example, the number of lower word lines penetrated by the lower channel LCH may be equal to or larger than the number of upper word lines penetrated by the upper channel UCH. Furthermore, the above-described structure and connection relationship of the channel structure CH disposed in the first cell region CELL1 may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 24, the first through-electrode THV1 may penetrate the common source line 320 and the plurality of word lines 330. However, this is illustrative, and the first through-electrode THV1 may additionally penetrate the second substrate 310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In implementations, the first through-electrode THV1 and the second through-electrode THV2 may be electrically connected through a first through-metal pattern 372d and a second through-metal pattern 472d. The first through-metal pattern 372d may be formed on a lower side of the first upper chip including the first cell region CELL1, and the second through-metal pattern 472d may be formed on an upper side of the second upper chip including the second cell region CELL2. The first through-electrode THV1 may be electrically connected with the first metal line 350c and the second metal line 360c. A lower VIA 371d may be formed between the first through-electrode THV1 and the first through-metal pattern 372d, and an upper VIA 471d may be formed between the second through-electrode THV2 and the second through-metal pattern 472d. The first through-metal pattern 372d and the second through-metal pattern 472d may be connected by a bonding method.

Furthermore, in the bit line bonding region BLBA, an upper metal pattern 252 may be formed on the uppermost metal layer of the peripheral circuit region PERI, and an upper metal pattern 392 having the same shape as the upper metal pattern 252 may be formed on the uppermost metal layer of the first cell region CELL1. The upper metal pattern 392 of the first cell region CELL1 and the upper metal pattern 252 of the peripheral circuit region PERI may be electrically connected to each other by a bonding method. In the bit line bonding region BLBA, the bit line 360c may be electrically connected with a page buffer included in the peripheral circuit region PERI. For example, some of the circuit elements 220c of the peripheral circuit region PERI may provide a page buffer, and the bit line 360c may be electrically connected with the circuit elements 220c providing the page buffer through an upper bonding metal 370c of the first cell region CELL1 and an upper bonding metal 270c of the peripheral circuit region PERI.

Continuously referring to FIG. 24, in the word line bonding region WLBA, the word lines 330 of the first cell region CELL1 may extend in a second direction (an X-axis direction) parallel to the upper surface of the second substrate 310 and may be connected with a plurality of cell contact plugs 340 (341 to 347). A first metal line 350b and a second metal line 360b may be sequentially connected to upper portions of the cell contact plugs 340 connected to the word lines 330. In the word line bonding region WLBA, the cell contact plugs 340 may be connected with the peripheral circuit region PERI through an upper bonding metal 370b of the first cell region CELL1 and an upper bonding metal 270b of the peripheral circuit region PERI.

The cell contact plugs 340 may be electrically connected with a row decoder included in the peripheral circuit region PERI. For example, some of the circuit elements 220b of the peripheral circuit region PERI may provide a row decoder, and the cell contact plugs 340 may be electrically connected with the circuit elements 220b providing the row decoder through the upper bonding metal 370b of the first cell region CELL1 and the upper bonding metal 270b of the peripheral circuit region PERI. In implementations, an operating voltage of the circuit elements 220b that provide the row decoder may differ from an operating voltage of the circuit elements 220c that provide the page buffer. For example, the operating voltage of the circuit elements 220c that provide the page buffer may be greater than the operating voltage of the circuit elements 220b that provide the row decoder.

Likewise, in the word line bonding region WLBA, the word lines 430 of the second cell region CELL2 may extend in the second direction (the X-axis direction) parallel to the upper surface of the third substrate 410 and may be connected with a plurality of cell contact plugs 440 (441 to 447). The cell contact plugs 440 may be connected with the peripheral circuit region PERI through an upper metal pattern of the second cell region CELL2, a lower metal pattern and an upper metal pattern of the first cell region CELL1, and a cell contact plug 348.

In the word line bonding region WLBA, the upper bonding metal 370b may be formed in the first cell region CELL1, and the upper bonding metal 270b may be formed in the peripheral circuit region PERI. The upper bonding metal 370b of the first cell region CELL1 and the upper bonding metal 270b of the peripheral circuit region PERI may be electrically connected to each other by a bonding method. The upper bonding metal 370b and the upper bonding metal 270b may be formed of aluminum, copper, or tungsten.

In the external pad bonding region PA, a lower metal pattern 371e may be formed on a lower portion of the first cell region CELL1, and an upper metal pattern 472a may be formed on an upper portion of the second cell region CELL2. The lower metal pattern 371e of the first cell region CELL1 and the upper metal pattern 472a of the second cell region CELL2 may be connected by a bonding method in the external pad bonding region PA. Likewise, an upper metal pattern 372a may be formed on an upper portion of the first cell region CELL1, and an upper metal pattern 272a may be formed on an upper portion of the peripheral circuit region PERI. The upper metal pattern 372a of the first cell region CELL1 and the upper metal pattern 272a of the peripheral circuit region PERI may be connected to each other by a bonding method.

Common source line contact plugs 380 and 480 may be disposed in the external pad bonding region PA. The common source line contact plugs 380 and 480 may be formed of a conductive material, such as metal, a metal compound, or doped poly-silicon. The common source line contact plug 380 of the first cell region CELL1 may be electrically connected with the common source line 320, and the common source line contact plug 480 of the second cell region CELL2 may be electrically connected with the common source line 420. A first metal line 350a and a second metal line 360a may be sequentially stacked on an upper portion of the common source line contact plug 380 of the first cell region CELL1, and a first metal line 450a and a second metal line 460a may be sequentially stacked on an upper portion of the common source line contact plug 480 of the second cell region CELL2.

Input/output pads 205, 405, and 406 may be disposed in the external pad bonding region PA. Referring to FIG. 24, a lower insulating layer 201 may cover a lower surface of the first substrate 210, and the first input/output pad 205 may be formed on the lower insulating layer 201. The first input/output pad 205 may be connected with at least one of the plurality of circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 and may electrically isolate the first input/output contact plug 203 from the first substrate 210.

An upper insulating layer 401 may be formed on the third substrate 410 to cover the upper surface of the third substrate 410. The second input/output pad 405 and/or the third input/output pad 406 may be disposed on the upper insulating layer 401. The second input/output pad 405 may be connected with at least one of the plurality of circuit elements 220a disposed in the peripheral circuit region PERI through second input/output contact plugs 403 and 303, and the third input/output pad 406 may be connected with at least one of the plurality of circuit elements 220a disposed in the peripheral circuit region PERI through third input/output contact plugs 404 and 304.

In implementations, the third substrate 410 may not be disposed in the regions in which the input/output contact plugs are disposed. For example, as illustrated in B, the third input/output contact plug 404 may be separated from the third substrate 410 in a direction parallel to the upper surface of the third substrate 410, may penetrate an interlayer insulating layer 415 of the second cell region CELL2, and may be connected to the third input/output pad 406. In this case, the third input/output contact plug 404 may be formed through various processes.

For example, as illustrated in B1, the third input/output contact plug 404 may extend in the third direction (the Z-axis direction) and may have an increasing diameter toward the upper insulating layer 401. That is, while the channel structure CH described with reference to Al has a decreasing diameter toward the upper insulating layer 401, the third input/output contact plug 404 may have an increasing diameter toward the upper insulating layer 401. For example, the third input/output contact plug 404 may be formed after the second cell region CELL2 and the first cell region CELL1 are coupled by a bonding method.

For example, as illustrated in B2, the third input/output contact plug 404 may extend in the third direction (the Z-axis direction) and may have a decreasing diameter toward the upper insulating layer 401. That is, likewise to the channel structure CH, the third input/output contact plug 404 may have a decreasing diameter toward the upper insulating layer 401. For example, the third input/output contact plug 404 may be formed together with the cell contact plugs 440 before the second cell region CELL2 and the first cell region CELL1 are coupled by a bonding method.

In implementations, an input/output contact plug may be disposed to overlap the third substrate 410. For example, as illustrated in C, the second input/output contact plug 403 may be formed through the interlayer insulating layer 415 of the second cell region CELL2 in the third direction (the Z-axis direction) and may be electrically connected to the second input/output pad 405 through the third substrate 410. In this case, a connection structure of the second input/output contact plug 403 and the second input/output pad 405 may be implemented in various ways.

For example, as illustrated in C1, an opening 408 may be formed through the third substrate 410, and the second input/output contact plug 403 may be directly connected to the second input/output pad 405 through the opening 408 formed in the third substrate 410. In this case, as illustrated in C1, the second input/output contact plug 403 may have an increasing diameter toward the second input/output pad 405. However, this is illustrative, and the second input/output contact plug 403 may have a decreasing diameter toward the second input/output pad 405.

For example, as illustrated in C2, the opening 408 may be formed through the third substrate 410, and a contact 407 may be formed in the opening 408. One end portion of the contact 407 may be connected to the second input/output pad 405, and an opposite end portion of the contact 407 may be connected to the second input/output contact plug 403. Accordingly, the second input/output contact plug 403 may be electrically connected to the second input/output pad 405 through the contact 407 in the opening 408. In this case, as illustrated in C2, the contact 407 may have an increasing diameter toward the second input/output pad 405, and the second input/output contact plug 403 may have a decreasing diameter toward the second input/output pad 405. For example, the third input/output contact plug 403 may be formed together with the cell contact plugs 440 before the second cell region CELL2 and the first cell region CELL1 are coupled by a bonding method, and the contact 407 may be formed after the second cell region CELL2 and the first cell region CELL1 are coupled by the bonding method.

For example, as illustrated in C3, a stopper 409 may be additionally formed on an upper surface of the opening 408 of the third substrate 410. The stopper 409 may be a metal line formed on the same layer as the common source line 420. However, this is illustrative, and the stopper 409 may be a metal line formed on the same layer as at least one of the word lines 430. The second input/output contact plug 403 may be electrically connected to the second input/output pad 405 through the contact 407 and the stopper 409.

Meanwhile, similarly to the second and third input/output contact plugs 403 and 404 of the second cell region CELL2, the second and third input/output contact plugs 303 and 304 of the first cell region CELL1 may have a decreasing diameter toward the lower metal pattern 371e or may have an increasing diameter toward the lower metal pattern 371e.

Meanwhile, in some implementations, a slit 411 may be formed in the third substrate 410. For example, the slit 411 may be formed at any position in the external pad bonding region PA. For example, as illustrated in D, the slit 411 may be located between the second input/output pad 405 and the cell contact plugs 440 when viewed on a plane. However, this is illustrative, and the slit 411 may be formed such that the second input/output pad 405 is located between the slit 411 and the cell contact plugs 440 when viewed on the plane.

For example, as illustrated in D1, the slit 411 may be formed through the third substrate 410. For example, the slit 411 may be used to prevent the third substrate 410 from being finely cracked when the opening 408 is formed. However, this is illustrative, and the slit 411 may be formed to have a depth ranging from about 60% to about 70% of the thickness of the third substrate 410.

For example, as illustrated in D2, a conductive material 412 may be formed in the slit 411. For example, the conductive material 412 may be used to discharge a leakage current generated while circuit elements in the external pad bonding region PA are driven. In this case, the conductive material 412 may be connected to an external ground line.

For example, as illustrated in D3, an insulating material 413 may be formed in the slit 411. For example, the insulating material 413 may be formed to electrically isolate the second input/output pad 405 and the second input/output contact plug 403 disposed in the external pad bonding region PA from the word line bonding region WLBA. An influence of a voltage provided through the second input/output pad 405 on a metal layer disposed on the third substrate 410 in the word line bonding region WLBA may be interrupted by forming the insulating material 413 in the slit 411.

Meanwhile, in some implementations, the first to third input/output pads 205, 405, and 406 may be selectively formed. For example, the memory device 500 may be implemented to include only the first input/output pad 205 disposed on the first substrate 201, only the second input/output pad 405 disposed on the third substrate 410, or only the third input/output pad 406 disposed on the upper insulating layer 401.

Meanwhile, in some implementations, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the peripheral circuit region PERI and the first cell region CELL1 are bonded to each other, and an insulating layer for covering an upper surface of the common source line 320 or a conductive layer for connection may be formed. Similarly, the third substrate 410 of the second cell region CELL2 may be removed before or after the first cell region CELL1 and the second cell region CELL2 are bonded to each other, and the upper insulating layer 401 for covering an upper surface of the common source line 420 or a conductive layer for connection may be formed.

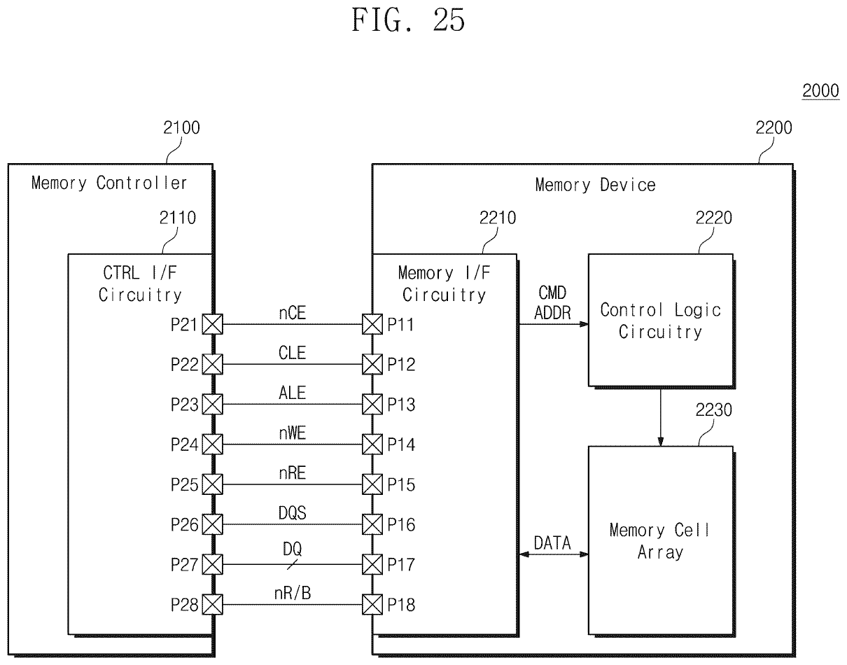

FIG. 25 is a block diagram of a memory system according to implementations. Referring to FIG. 25, the memory system 2000 may include a memory device 2200 and a memory controller 2100.

The memory device 2200 may include first to eighth pins P11 to P18, a memory interface circuitry 2210, a control logic circuitry 2220, and a memory cell array 2230.

The memory interface circuitry 2210 may receive a chip enable signal nCE from the memory controller 2100 through the first pin P11. The memory interface circuitry 2210 may transmit and receive signals to and from the memory controller 2100 through the second to eighth pins P12 to P18 in response to the chip enable signal nCE. For example, when the chip enable signal nCE is in an enable state (e.g., a low level), the memory interface circuitry 2210 may transmit and receive signals to and from the memory controller 2100 through the second to eighth pins P12 to P18.

The memory interface circuitry 2210 may receive a command latch enable signal CLE, an address latch enable signal ALE, and a write enable signal nWE from the memory controller 2100 through the second to fourth pins P12 to P14. The memory interface circuitry 2210 may receive a data signal DQ from the memory controller 2100 through the seventh pin P17 or transmit the data signal DQ to the memory controller 2100. A command CMD, an address ADDR, and data may be transmitted via the data signal DQ. For example, the data signal DQ may be transmitted through a plurality of data signal lines. In this case, the seventh pin P17 may include a plurality of pins respectively corresponding to a plurality of data signals DQ(s).

The memory interface circuitry 2210 may obtain the command CMD from the data signal DQ, which is received in an enable section (e.g., a high-level state) of the command latch enable signal CLE based on toggle time points of the write enable signal nWE. The memory interface circuitry 2210 may obtain the address ADDR from the data signal DQ, which is received in an enable section (e.g., a high-level state) of the address latch enable signal ALE based on the toggle time points of the write enable signal nWE.

In example implementations, the write enable signal nWE may be maintained at a static state (e.g., a high level or a low level) and toggle between the high level and the low level. For example, the write enable signal nWE may toggle in a section in which the command CMD or the address ADDR is transmitted. Thus, the memory interface circuitry 2210 may obtain the command CMD or the address ADDR based on toggle time points of the write enable signal nWE.

The memory interface circuitry 2210 may receive a read enable signal nRE from the memory controller 2100 through the fifth pin P15. The memory interface circuitry 2210 may receive a data strobe signal DQS from the memory controller 2100 through the sixth pin P16 or transmit the data strobe signal DQS to the memory controller 2100.

In a data (DATA) output operation of the memory device 2200, the memory interface circuitry 2210 may receive the read enable signal nRE, which toggles through the fifth pin P15, before outputting the data DATA. The memory interface circuitry 2210 may generate the data strobe signal DQS, which toggles based on the toggling of the read enable signal nRE. For example, the memory interface circuitry 2210 may generate a data strobe signal DQS, which starts toggling after a predetermined delay (e.g., tDQSRE), based on a toggling start time of the read enable signal nRE. The memory interface circuitry 2210 may transmit the data signal DQ including the data DATA based on a toggle time point of the data strobe signal DQS. Thus, the data DATA may be aligned with the toggle time point of the data strobe signal DQS and transmitted to the memory controller 2100.

In a data (DATA) input operation of the memory device 2200, when the data signal DQ including the data DATA is received from the memory controller 2100, the memory interface circuitry 2210 may receive the data strobe signal DQS, which toggles, along with the data DATA from the memory controller 2100. The memory interface circuitry 2210 may obtain the data DATA from the data signal DQ based on toggle time points of the data strobe signal DQS. For example, the memory interface circuitry 2210 may sample the data signal DQ at rising and falling edges of the data strobe signal DQS and obtain the data DATA.

The memory interface circuitry 2210 may transmit a ready/busy output signal nR/B to the memory controller 2100 through the eighth pin P18. The memory interface circuitry 2210 may transmit state information of the memory device 2200 through the ready/busy output signal nR/B to the memory controller 2100. When the memory device 2200 is in a busy state (i.e., when operations are being performed in the memory device 2200), the memory interface circuitry 2210 may transmit a ready/busy output signal nR/B indicating the busy state to the memory controller 2100. When the memory device 2200 is in a ready state (i.e., when operations are not performed or completed in the memory device 2200), the memory interface circuitry 2210 may transmit a ready/busy output signal nR/B indicating the ready state to the memory controller 2100. For example, while the memory device 2200 is reading data DATA from the memory cell array 2230 in response to a page read command, the memory interface circuitry 2210 may transmit a ready/busy output signal nR/B indicating a busy state (e.g., a low level) to the memory controller 2100. For example, while the memory device 2200 is programming data DATA to the memory cell array 2230 in response to a program command, the memory interface circuitry 2210 may transmit a ready/busy output signal nR/B indicating the busy state to the memory controller 2100.

The control logic circuitry 2220 may control all operations of the memory device 2200. The control logic circuitry 2220 may receive the command/address CMD/ADDR obtained from the memory interface circuitry 2210. The control logic circuitry 2220 may generate control signals for controlling other components of the memory device 2200 in response to the received command/address CMD/ADDR. For example, the control logic circuitry 2220 may generate various control signals for programming data DATA to the memory cell array 2230 or reading the data DATA from the memory cell array 2230.

The memory cell array 2230 may store the data DATA obtained from the memory interface circuitry 2210, via the control of the control logic circuitry 2220. The memory cell array 2230 may output the stored data DATA to the memory interface circuitry 2210 via the control of the control logic circuitry 2220.

The memory cell array 2230 may include a plurality of memory cells. For example, the plurality of memory cells may be flash memory cells. However, the memory cells are not limited thereto, and the memory cells may be RRAM cells, FRAM cells, PRAM cells, thyristor RAM (TRAM) cells, or MRAM cells. Hereinafter, implementations in which the memory cells are NAND flash memory cells will mainly be described.

The memory controller 2100 may include first to eighth pins P21 to P28 and a controller interface circuitry 2110. The first to eighth pins P21 to P28 may respectively correspond to the first to eighth pins P11 to P18 of the memory device 2200.

The controller interface circuitry 2110 may transmit a chip enable signal nCE to the memory device 2200 through the first pin P21. The controller interface circuitry 2110 may transmit and receive signals to and from the memory device 2200, which is selected by the chip enable signal nCE, through the second to eighth pins P22 to P28.

The controller interface circuitry 2110 may transmit the command latch enable signal CLE, the address latch enable signal ALE, and the write enable signal nWE to the memory device 2200 through the second to fourth pins P22 to P24. The controller interface circuitry 2110 may transmit or receive the data signal DQ to and from the memory device 2200 through the seventh pin P27.

The controller interface circuitry 2110 may transmit the data signal DQ including the command CMD or the address ADDR to the memory device 2200 along with the write enable signal nWE, which toggles. The controller interface circuitry 2110 may transmit the data signal DQ including the command CMD to the memory device 2200 by transmitting a command latch enable signal CLE having an enable state. Also, the controller interface circuitry 2110 may transmit the data signal DQ including the address ADDR to the memory device 2200 by transmitting an address latch enable signal ALE having an enable state.

The controller interface circuitry 2110 may transmit the read enable signal nRE to the memory device 2200 through the fifth pin P25. The controller interface circuitry 2110 may receive or transmit the data strobe signal DQS from or to the memory device 2200 through the sixth pin P26.

In a data (DATA) output operation of the memory device 2200, the controller interface circuitry 2110 may generate a read enable signal nRE, which toggles, and transmit the read enable signal nRE to the memory device 2200. For example, before outputting data DATA, the controller interface circuitry 2110 may generate a read enable signal nRE, which is changed from a static state (e.g., a high level or a low level) to a toggling state. Thus, the memory device 2200 may generate a data strobe signal DQS, which toggles, based on the read enable signal nRE. The controller interface circuitry 2110 may receive the data signal DQ including the data DATA along with the data strobe signal DQS, which toggles, from the memory device 2200. The controller interface circuitry 2110 may obtain the data DATA from the data signal DQ based on a toggle time point of the data strobe signal DQS.

In a data (DATA) input operation of the memory device 2200, the controller interface circuitry 2110 may generate a data strobe signal DQS, which toggles. For example, before transmitting data DATA, the controller interface circuitry 2110 may generate a data strobe signal DQS, which is changed from a static state (e.g., a high level or a low level) to a toggling state. The controller interface circuitry 2110 may transmit the data signal DQ including the data DATA to the memory device 2200 based on toggle time points of the data strobe signal DQS.

The controller interface circuitry 2110 may receive a ready/busy output signal nR/B from the memory device 2200 through the eighth pin P28. The controller interface circuitry 2110 may determine state information of the memory device 2200 based on the ready/busy output signal nR/B.

In implementations, the memory cell array 2230 of the memory device 2200 may include a plurality of memory blocks. The plurality of memory blocks may have one of various structures described with reference to FIGS. 1 to 22 and may include a plurality of ground selection transistors programmed based on the GSL coding pattern described with reference to FIGS. 1 to 22. The memory device 2200 may control a plurality of ground selection lines, based on the method described with reference to FIGS. 1 to 22.

In implementations, the ground selection transistors included in each of the plurality of memory blocks may be programmed based on the GSL coding pattern in the process of manufacturing the memory device 2200. Alternatively, the memory device 2200 may program the ground selection transistors included in each of the plurality of memory blocks based on the GSL coding pattern, under control of the memory controller 2100. In implementations, when the erase operation on the memory block is performed, the memory device 2200 may perform the program operation on ground selection transistors based on the GSL coding pattern.

According to the present disclosure, a memory device may include a plurality of memory blocks, and each of the plurality of the memory blocks may include a plurality of cell strings. The plurality of cell strings may be respectively connected to a plurality of string selection lines and may share the same ground selection line. In each of the plurality of cell strings, the memory device may program ground selection transistors such that at least two adjacent ground selection transistors have the same program state. In this case, as a cell characteristic of a ground selection transistor is improved, the reliability and performance of the memory device are improved.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

1. A memory device comprising:
a first cell string provided between a first bit line and a common source line and including a first string selection transistor that is connected to a first string selection line and first ground selection transistors respectively connected to a plurality of ground selection lines; and
a second cell string provided between the first bit line and the common source line and including a second string selection transistor that is connected to a second string selection line and second ground selection transistors respectively connected to the plurality of ground selection lines,
wherein at least two first ground selection transistors among the first ground selection transistors are configured to have a first program state and one or more remaining first ground selection transistors among the first ground selection transistors are configured to have an erase state, and
wherein at least two second ground selection transistors among the second ground selection transistors are configured to have the first program state and one or more remaining second ground selection transistors among the second ground selection transistors are configured to have the erase state.

2. The memory device of claim 1, wherein the at least two first ground selection transistors are adjacent to each other, and
wherein the at least two second ground selection transistors are adjacent to each other.

3. The memory device of claim 1, wherein the first cell string further includes a first plurality of memory cells respectively connected to a plurality of word lines, and
wherein the second cell string further includes a second plurality of memory cells respectively connected to the plurality of word lines.

4. The memory device of claim 3, wherein the first cell string further includes:
a first dummy ground selection transistor provided between the common source line and the first ground selection transistors and connected to a first dummy ground selection line; and
a second dummy ground selection transistor provided between the first plurality of memory cells and the first ground selection transistors and connected to a second dummy ground selection line, and
wherein the second cell string further includes:
a third dummy ground selection transistor provided between the common source line and the second ground selection transistors and connected to the first dummy ground selection line; and
a fourth dummy ground selection transistor provided between the second plurality of memory cells and the second ground selection transistors and connected to the second dummy ground selection line.

5. The memory device of claim 4, wherein the first dummy ground selection transistor has the same state as a lowermost first ground selection transistor among the first ground selection transistors,
wherein the second dummy ground selection transistor has the same state as an uppermost first ground selection transistor among the first ground selection transistors,
wherein the third dummy ground selection transistor has the same state as a lowermost second ground selection transistor among the second ground selection transistors,
wherein the fourth dummy ground selection transistor has the same state as an uppermost second ground selection transistor among the second ground selection transistors,
wherein the lowermost first ground selection transistor indicates a ground selection transistor adjacent to the first dummy ground selection transistor from among the first ground selection transistors,
wherein the uppermost first ground selection transistor indicates a ground selection transistor adjacent to the second dummy ground selection transistor from among the first ground selection transistors,
wherein the lowermost second ground selection transistor is a ground selection transistor adjacent to the third dummy ground selection transistor from among the second ground selection transistors, and
wherein the uppermost second ground selection transistor indicates a ground selection transistor adjacent to the fourth dummy ground selection transistor from among the second ground selection transistors.

6. The memory device of claim 1, wherein one of the at least two first ground selection transistors and one of the remaining second ground selection transistors are connected to the same ground selection line.

7. The memory device of claim 1, further comprising:
a third cell string provided between the first bit line and the common source line and including a third string selection transistor that is connected to a third string selection line and third ground selection transistors respectively connected to the plurality of ground selection lines; and
a fourth cell string provided between the first bit line and the common source line and including a fourth string selection transistor that is connected to a fourth string selection line and fourth ground selection transistors respectively connected to the plurality of ground selection lines,
wherein at least two third ground selection transistors among the third ground selection transistors are configured to have the first program state and one or more remaining third ground selection transistors among the third ground selection transistors are configured to have the erase state, and
wherein at least two fourth ground selection transistors among the fourth ground selection transistors are configured to have the first program state and one or more remaining fourth ground selection transistors among the fourth ground selection transistors are configured to have the erase state.

8. The memory device of claim 7, further comprising:
a fifth cell string provided between the first bit line and the common source line and including a fifth string selection transistor that is connected to a fifth string selection line and fifth ground selection transistors respectively connected to the plurality of ground selection lines;
a sixth cell string provided between the first bit line and the common source line and including a sixth string selection transistor that is connected to a sixth string selection line and sixth ground selection transistors respectively connected to the plurality of ground selection lines;
a seventh cell string provided between the first bit line and the common source line and including a seventh string selection transistor that is connected to a seventh string selection line and seventh ground selection transistors respectively connected to the plurality of ground selection lines; and
an eighth cell string provided between the first bit line and the common source line and including an eighth string selection transistor that is connected to an eighth string selection line and eighth ground selection transistors respectively connected to the plurality of ground selection lines.

9. The memory device of claim 8, wherein a number of the plurality of ground selection lines is 4 or 8.

10. The memory device of claim 8, wherein a number of the at least two first ground selection transistors is 2, 4, or 6.

11. The memory device of claim 1, wherein, when the first cell string is selected,
a first on-voltage is applied to at least two ground selection lines connected to the at least two first ground selection transistors from among the plurality of ground selection lines, and
a second on-voltage lower than the first on-voltage is applied to remaining ground selection lines among the plurality of ground selection lines.

12. The memory device of claim 1, wherein a program voltage is applied simultaneously to at least two first ground selection lines connected to the at least two first ground selection transistors from among the plurality of ground selection lines such that the at least two first ground selection transistors are simultaneously programmed, and
wherein the program voltage is applied simultaneously to at least two second ground selection lines connected to the at least two second ground selection transistors from among the plurality of ground selection lines such that the at least two second ground selection transistors are simultaneously programmed.

13. The memory device of claim 1, further comprising:
a third cell string provided between a second bit line and the common source line and including a third string selection transistor that is connected to the first string selection line and third ground selection transistors respectively connected to the plurality of ground selection lines,
wherein at least two third ground selection transistors among the third ground selection transistors are configured to have the first program state and one or more remaining third ground selection transistors among the third ground selection transistors are configured to have the erase state, and
wherein the at least two first ground selection transistors and the at least two third ground selection transistors are respectively connected to the same ground selection lines.

14. A memory device comprising:
a first cell string connected to a first bit line, a first string selection line, and a plurality of ground selection lines;
a second cell string connected to the first bit line, a second string selection line, and the plurality of ground selection lines;
a third cell string connected to the first bit line, a third string selection line, and the plurality of ground selection lines; and
a fourth cell string connected to the first bit line, a fourth string selection line, and the plurality of ground selection lines,
wherein, when the first cell string is selected, a first on-voltage is applied to a first ground selection line and a second ground selection line among the plurality of ground selection lines, and a second on-voltage lower than the first on-voltage is applied to remaining ground selection lines among the plurality of ground selection lines other than the first and second ground selection lines, and
wherein, when the second cell string is selected, the first on-voltage is applied to the second ground selection line and a third ground selection line among the plurality of ground selection lines, and the second on-voltage is applied to remaining ground selection lines among the plurality of ground selection lines other than the second and third ground selection lines.

15. The memory device of claim 14, wherein the first ground selection line and the second ground selection line are adjacent to each other, and
wherein the second ground selection line and the third ground selection line are adjacent to each other.

16. The memory device of claim 15, wherein, when the third cell string is selected, the first on-voltage is applied to the third ground selection line and to a fourth ground selection line among the plurality of ground selection lines, and the second on-voltage is applied to remaining ground selection lines among the plurality of ground selection lines other than the third and fourth ground selection lines, and
wherein the third ground selection line and the fourth ground selection line are adjacent to each other.

17. The memory device of claim 14, further comprising:
a fifth cell string connected to the first bit line, a fifth string selection line, and the plurality of ground selection lines;
a sixth cell string connected to the first bit line, a sixth string selection line, and the plurality of ground selection lines;
a seventh cell string connected to the first bit line, a seventh string selection line, and the plurality of ground selection lines; and
an eighth cell string connected to the first bit line, an eighth string selection line, and the plurality of ground selection lines.

18. The memory device of claim 17, wherein a number of the plurality of ground selection lines is 8.

19. The memory device of claim 17, wherein each of the first to eighth cell strings is connected to a plurality of word lines, a first dummy ground selection line, and a second dummy ground selection line,
wherein the first dummy ground selection line is provided between a substrate and the plurality of ground selection lines, and
wherein the second dummy ground selection line is provided between the plurality of word lines and the plurality of ground selection lines.

20. An operation method of a memory device which includes a plurality of cell strings provided between a bit line and a common source line, the plurality of cell strings being respectively connected to a plurality of string selection lines and each of the plurality of cell strings being connected to a plurality of word lines and a plurality of ground selection lines, the method comprising:
selecting at least two ground selection lines among the plurality of ground selection lines;
applying a program voltage simultaneously to the at least two ground selection lines; and
applying a verify voltage simultaneously to the at least two ground selection lines.

21.-23. (canceled)
